(19) United States
(12) Patent Application Publication
(10) Pub. No.: US 2022/0181580 A1
(43) Pub. Date: Jun. 9, 2022

(54) PASSIVATION METHOD

(71) Applicant: OXFORD UNIVERSITY INNOVATION LIMITED, Oxford (GB)

(72) Inventors: Julian S.W. Godding, Oxford (GB); Bernard Wenger, Oxford (GB); Henry James Snaith, Oxford (GB)

(21) Appl. No.: 17/436,843

(22) PCT Filed: Mar. 6, 2020
(86) PCT No.: PCT/GB2020/050547

§ 371 Date: Sep. 7, 2021

(30) Foreign Application Priority Data
Mar. 7, 2019 (GB) 1903085.7

(51) Int. Cl. H01L 51/52; C09K 11/06; H01L 51/00; C09K 11/66; H01L 51/44; H01G 9/20

(52) U.S. Cl. CPC H01L 51/5253; C09K 11/06; H01L 51/0077; C09K 2211/188; H01L 51/448; H01L 51/0001; H01G 9/2059; C09K 11/665

(57) ABSTRACT

The invention provides a process for producing a passivated semiconductor, which process comprises treating a semiconductor with a passivating agent, wherein: the semiconductor comprises a crystalline compound comprising: (i) one or more first cations (A); (ii) one or more metal cations (M); and (iii) one or more anions (X); and the passivating agent comprises a compound comprising an oxygen-oxygen single bond. A composition and the use of a passivating agent are also provided.

### FIELD OF THE INVENTION

The present invention relates to a process for producing a passivated semiconductor. Also described is a composition comprising a passivating agent and the use of a passivating agent.

The project leading to this application has received funding from the European Union's Horizon 2020 research and innovation programme under the Marie Skłodowska-Curie grant agreement no: 706552.

### BACKGROUND OF THE INVENTION

The progress of metal halide perovskites for use in photovoltaics, LEDs and other optoelectronic devices has been remarkable. Within less than a decade, perovskites have emerged as pioneering next-generation photovoltaic materials due to their simple processing routes and power-conversion efficiencies (PCE) that now surpass 23%. However, whilst great strides have been made in photovoltaic performance, the understanding of the fundamental chemical reactivity of these organic-inorganic materials is still incomplete, with implications on their long-term stability.

The environment, and in particular exposure to light and oxygen, can affect the properties of perovskites such as the archetypal methylammonium (MA) lead iodide perovskite, MAPbI₃. There is currently no agreement on whether the response of perovskites to oxygen and light in a humid environment is beneficial or detrimental to their utility as photoactive materials.

Brenes et al (Adv Mater 2018, 30, 1706208) describes an enhancement of photoluminescence for a perovskite following light-soaking in the presence of oxygen. This phenomenon is known as photo-brightening. Aristidou et al (Nature Communications 8, 15218 (2017)) describes oxygen- and light-induced degradation of perovskite solar cells. Anaya et al (J Phys Chem Lett 2018, 9, 3891-3896) describes an investigation of the effect of oxygen and light on the photoluminescence activation of organic metal halide perovskites. Palazon et al (ACS Appl Nano Mater 2018, 1, 5396-5400) describes the effect of oxygen plasma on nanocrystals of perovskite compounds. A computational study of the effect of oxygen on methylammonium lead iodide is presented in Ouyang et al (J Mater Chem A 2019, 7, 2275-2282)

To the extent that photo-brightening is beneficial for the optical properties of photoactive materials such as perovskites and other A/M/X materials, the process of light-soaking in air requires conditions that are too difficult to control to be easily used during manufacture. Furthermore, photo-brightening does not appear to apply for all A/M/X materials in a predictable way and seems to be most effective for perovskites containing a methylammonium cation. Photo-brightening is also a time-consuming process which typically takes several hours to be effective.

It is desirable to develop a method for increasing optical properties such as photoluminescence of A/M/X materials such as perovskites which is scalable, fast and effective. It is also desirable to develop a method which can use non-toxic materials. It would further be beneficial to develop a method which may be applied to a wide range of different A/M/X materials, including those which do not include organic cations. In addition, a method which is controllable and reproducible is desirable.

### SUMMARY OF THE INVENTION

The inventors have investigated the mechanism of photo-brightening and have determined the role of certain oxygen-containing compounds in the mechanism. On the basis of this investigation, it has been found that the problems associated with photo-brightening may be circumvented and only the benefits maintained, by directly treating A/M/X materials with oxygen-containing compounds. The oxygen-containing compounds have been observed to passivate defects in the A/M/X materials in a controllable manner and thereby enhance the optical properties of the materials. The inventors have accordingly developed a process for producing a passivated semiconductor which is reproducible, reliable and effective. The process has been found to lead to significant and unexpected improvements in device performance.

The invention accordingly provides a process for producing a passivated semiconductor, which process comprises treating a semiconductor with a passivating agent, wherein: the semiconductor comprises a crystalline compound comprising: (i) one or more first cations (A); (ii) one or more metal cations (M); and (iii) one or more anions (X); and the passivating agent comprises a compound comprising an oxygen-oxygen single bond.

The invention also provides a composition comprising: (a) a semiconductor comprising a crystalline compound comprising: (i) one or more first cations (A); (ii) one or more metal cations (M); and (iii) one or more anions (X); and (b) a passivating agent comprising a compound which comprises an oxygen-oxygen single bond, wherein the concentration of the passivating agent is greater than or equal to 0.001 mol % relative to the amount of the semiconductor.

Further provided by the invention is the use of a composition comprising a passivating agent for passivating a semiconductor which is illuminated with an intensity of no greater than 0.5 kW/m² during passivation, wherein: the semiconductor comprises a crystalline compound comprising: (i) one or more first cations (A); (ii) one or more metal cations (M); and (iii) one or more anions (X); and the passivating agent comprises a compound comprising an oxygen-oxygen single bond or an oxygen-oxygen double bond.

### BRIEF DESCRIPTION OF THE FIGURES

FIG. 1 shows a schematic diagram of the set up used to expose a semiconductor to gaseous hydrogen peroxide, using an enclosed chamber (1), a holder for reactants (2), a heat source (3), urea hydrogen peroxide (4) and a semiconductor (5).

FIG. 2 shows steady state photoluminescence measurements of control and treated films of FA_{0.83}Cs_{0.17}Pb(Br_{0.1}I_{0.9})₃ treated in low concentrations of H₂O₂ in isopropanol (IPA) via a solution deposition method.

FIG. 3 shows the intensity dependence of external photoluminescence quantum efficiency (PLQE) values for films of FA_{0.83}Cs_{0.17}Pb(Br_{0.1}I_{0.9})₃ treated with H₂O₂ for various exposure times via the gas deposition method using urea hydrogen peroxide.

FIG. 4 shows the powder x-ray diffraction (XRD) pattern of a FA_{0.83}Cs_{0.17}Pb(Br_{0.1}I_{0.9})₃ thin film before and after treatment with H₂O₂ via the gas deposition method.

FIG. 5 shows PLQE for films treated with the different passivation agents under 1 sun irradiance. The different passivating agents are phenethylammonium iodide (PEAI) and butylammonium iodide (BAI).

FIG. 6 shows steady state photoluminescence (PL) spectra of inorganic CsPb(Br_{0.1}I_{0.9})₃ thin films treated with hydrogen peroxide via the urea hydrogen peroxide (UHP) gas deposition method for five minutes compared with the untreated control film.

FIG. 7 shows steady state photoluminescence measurement of film of FA_{0.83}Cs_{0.17}Pb(Br_{0.1}I_{0.9})₃ after treatment with an exposure to oxygen plasma, compared to a control film.

FIG. 8 shows steady state photoluminescence measurement of film of MAPbI₃ after treatment with an exposure to 30% ozone gas in oxygen, compared to a control.

FIG. 9 shows current density-voltage (J-V) characteristics of FA_{0.83}Cs_{0.17}Pb(Br_{0.1}I_{0.9})₃ devices treated by H₂O₂ via the gas deposition method compared to the control device, measured under AM1.5 100 mW/cm² simulated sunlight. P-i-n devices were treated with UHP for 40 s and n-i-p devices were treated for 70 s. (a) Current-voltage characteristics of the champion p-i-n devices in the light and dark. (b) and (c) Steady-state photocurrents and efficiencies of the devices. (d) Current-voltage characteristics of the champion inverted n-i-p devices in the light and dark. (e) and (f) Steady-state photocurrents and efficiencies of the devices. Steady-state measurements were taken by holding the devices at their JV determined maximum power point for one minute.

FIG. 10 shows device parameters for forward and reverse current density-voltage (J-V) scans of FA_{0.83}Cs_{0.17}Pb(Br_{0.1}I_{0.9})₃ devices in n-i-p configuration treated by H₂O₂ via the gas deposition method using UHP compared to the control device.

FIG. 11 shows device parameters for forward and reverse current density-voltage (J-V) scans of FA_{0.83}Cs_{0.17}Pb(Br_{0.1}I_{0.9})₃ devices in p-i-n configuration treated by H₂O₂ via the gas deposition method using UHP compared to the control device.

FIG. 12 shows the effect of annealing on PLQE of hydrogen peroxide treated perovskite films.

FIG. 13 shows the UV-Vis spectra of hydrogen peroxide treated perovskite films.

### DETAILED DESCRIPTION OF THE INVENTION

### Definitions

The term “crystalline material” as used herein refers to a material having a crystal structure. The term “crystalline A/M/X material” as used herein refers to a material with a crystal structure which comprises one or more A ions, one or more M ions, and one or more X ions. The A ions and M ions are typically cations. The X ions are typically anions. A/M/X materials typically do not comprise any further types of ions.

The term “perovskite” as used herein refers to a material with a crystal structure related to that of CaTiO₃ or a material comprising a layer of material, which layer has a structure related to that of CaTiO₃. The structure of CaTiO₃ can be represented by the formula ABX₃, wherein A and B are cations of different sizes and X is an anion. In the unit cell, the A cations are at (0, 0, 0), the B cations are at (½, ½, ½) and the X anions are at (½, ½, 0). The A cation is usually larger than the B cation. The skilled person will appreciate that when A, B and X are varied, the different ion sizes may cause the structure of the perovskite material to distort away from the structure adopted by CaTiO₃ to a lower-symmetry distorted structure. The symmetry will also be lower if the material comprises a layer that has a structure related to that of CaTiO₃. Materials comprising a layer of perovskite material are well known. For instance, the structure of materials adopting the K₂NiF₄-type structure comprises a layer of perovskite material. The skilled person will appreciate that a perovskite material can be represented by the formula [A][B][X]₃, wherein [A] is at least one cation, [B] is at least one cation and [X] is at least one anion. When the perovskite comprises more than one A cation, the different A cations may be distributed over the A sites in an ordered or disordered way. When the perovskite comprises more than one B cation, the different B cations may be distributed over the B sites in an ordered or disordered way. When the perovskite comprises more than one X anion, the different X anions may be distributed over the X sites in an ordered or disordered way. The symmetry of a perovskite comprising more than one A cation, more than one B cation or more than one X anion, will be lower than that of CaTiO₃. For layered perovskites the stoichiometry can change between the A, B and X ions. As an example, the [A]₂[B][X]₄ structure can be adopted if the A cation has a too large an ionic radius to fit within the 3D perovskite structure. The term “perovskite” also includes A/M/X materials adopting a Ruddlesden-Popper phase. Ruddlesden-Popper phase refers to a perovskite with a mixture of layered and 3D components. Such perovskites can adopt the crystal structure, Aₙ₋₁A′₂MₙX₃ₙ₊₁, where A and A′ are different cations and n is an integer from 1 to 8, or from 2 to 6. The term “mixed 2D and 3D” perovskite is used to refer to a perovskite film within which there exists both regions, or domains, of AMX₃ and Aₙ₋₁A′₂MₙX₃ₙ₊₁ perovskite phases.

The term “metal halide perovskite” as used herein refers to a perovskite, the formula of which contains at least one metal cation and at least one halide anion.

The term “hexahalometallate”, as used herein, refers to a compound which comprises an anion of the formula [MX₆]ⁿ⁻ wherein M is a metal atom, each X is independently a halide anion and n is an integer from 1 to 4. A hexahalometallate may have the structure A₂MX₆.

The term “monocation”, as used herein, refers to any cation with a single positive charge, i.e. a cation of formula A⁺ where A is any moiety, for instance a metal atom or an organic moiety. The term “dication”, as used herein, refers to any cation with a double positive charge, i.e. a cation of formula A²⁺ where A is any moiety, for instance a metal atom or an organic moiety. The term “trication”, as used herein, refers to any cation with a double positive charge, i.e. a cation of formula A³⁺ where A is any moiety, for instance a metal atom or an organic moiety. The term “tetracation”, as used herein, refers to any cation with a quadruple positive charge, i.e. a cation of formula A⁴⁺ where A is any moiety, for instance a metal atom.

The term “alkyl” as used herein refers to a linear or branched chain saturated hydrocarbon radical. An alkyl group may be a C₁₋₂₀ alkyl group, a C₁₋₁₄ alkyl group, a C₁₋₁₀ alkyl group, a C₁₋₆ alkyl group or a C₁₋₄ alkyl group. Examples of a C₁₋₁₀ alkyl group are methyl, ethyl, propyl, butyl, pentyl, hexyl, heptyl, octyl, nonyl or decyl. Examples of C₁₋₆ alkyl groups are methyl, ethyl, propyl, butyl, pentyl or hexyl. Examples of C₁₋₄ alkyl groups are methyl, ethyl, i-propyl, n-propyl, t-butyl, s-butyl or n-butyl. If the term “alkyl” is used without a prefix specifying the number of carbons anywhere herein, it has from 1 to 6 carbons (and this also applies to any other organic group referred to herein).

The term “cycloalkyl” as used herein refers to a saturated or partially unsaturated cyclic hydrocarbon radical. A cycloalkyl group may be a C₃₋₁₀ cycloalkyl group, a C₃₋₈ cycloalkyl group or a C₃₋₆ cycloalkyl group. Examples of a C₃₋₈ cycloalkyl group include cyclopropyl, cyclobutyl, cyclopentyl, cyclohexyl, cyclohexenyl, cyclohex-1,3-dienyl, cycloheptyl and cyclooctyl. Examples of a C₃₋₆ cycloalkyl group include cyclopropyl, cyclobutyl, cyclopentyl and cyclohexyl.

The term “alkenyl” as used herein refers to a linear or branched chain hydrocarbon radical comprising one or more double bonds. An alkenyl group may be a C₂₋₂₀ alkenyl group, a C₂₋₁₄ alkenyl group, a C₂₋₁₀ alkenyl group, a C₂₋₆ alkenyl group or a C₂₋₄ alkenyl group.

Examples of a C₂₋₁₀ alkenyl group are ethenyl (vinyl), propenyl, butenyl, pentenyl, hexenyl, heptenyl, octenyl, nonenyl and decenyl. Examples of C₂₋₆ alkenyl groups are ethenyl, propenyl, butenyl, pentenyl and hexenyl. Examples of C₂₋₄ alkenyl groups are ethenyl, i-propenyl, n-propenyl, s-butenyl and n-butenyl. Alkenyl groups typically comprise one or two double bonds.

The term “alkynyl” as used herein refers to a linear or branched chain hydrocarbon radical comprising one or more triple bonds. An alkynyl group may be a C₂₋₂₀ alkynyl group, a C₂₋₁₄ alkynyl group, a C₂₋₁₀ alkynyl group, a C₂₋₆ alkynyl group or a C₂₋₄ alkynyl group. Examples of a C₂₋₁₀ alkynyl group are ethynyl, propynyl, butynyl, pentynyl, hexynyl, heptynyl, octynyl, nonynyl and decynyl. Examples of C₁₋₆ alkynyl groups are ethynyl, propynyl, butynyl, pentynyl and hexynyl. Alkynyl groups typically comprise one or two triple bonds.

The term “aryl” as used herein refers to a monocyclic, bicyclic or polycyclic aromatic ring which contains from 6 to 14 carbon atoms, typically from 6 to 10 carbon atoms, in the ring portion. Examples include phenyl, naphthyl, indenyl, indanyl, anthrecenyl and pyrenyl groups. The term “aryl group” as used herein includes heteroaryl groups. The term “heteroaryl” as used herein refers to monocyclic or bicyclic heteroaromatic rings which typically contains from six to ten atoms in the ring portion including one or more heteroatoms. A heteroaryl group is generally a 5- or 6-membered ring, containing at least one heteroatom selected from O, S, N, P, Se and Si. It may contain, for example, one, two or three heteroatoms. Examples of heteroaryl groups include pyridyl, pyrazinyl, pyrimidinyl, pyridazinyl, furanyl, thienyl, pyrazolidinyl, pyrrolyl, oxazolyl, oxadiazolyl, isoxazolyl, thiadiazolyl, thiazolyl, isothiazolyl, imidazolyl, pyrazolyl, quinolyl and isoquinolyl.

The term “substituted” as used herein in the context of substituted organic groups refers to an organic group which bears one or more substituents selected from C₁₋₁₀ alkyl, aryl (as defined herein), cyano, amino, nitro, C₁₋₁₀ alkylamino, di(C₁₋₁₀)alkylamino, arylamino, diarylamino, aryl(C₁₋₁₀)alkylamino, amido, acylamido, hydroxy, oxo, halo, carboxy, ester, acyl, acyloxy, C₁₋₁₀ alkoxy, aryloxy, halo(C₁₋₁₀)alkyl, sulfonic acid, thiol, C₁₋₁₀ alkylthio, arylthio, sulfonyl, phosphoric acid, phosphate ester, phosphonic acid and phosphonate ester. Examples of substituted alkyl groups include haloalkyl, perhaloalkyl, hydroxyalkyl, aminoalkyl, alkoxyalkyl and alkaryl groups. When a group is substituted, it may bear 1, 2 or 3 substituents. For instance, a substituted group may have 1 or 2 substitutents.

The term “porous” as used herein refers to a material within which pores are arranged. Thus, for instance, in a porous scaffold material the pores are volumes within the scaffold where there is no scaffold material. The individual pores may be the same size or different sizes. The size of the pores is defined as the “pore size”. The limiting size of a pore, for most phenomena in which porous solids are involved, is that of its smallest dimension which, in the absence of any further precision, is referred to as the width of the pore (i.e. the width of a slit-shaped pore, the diameter of a cylindrical or spherical pore, etc.). To avoid a misleading change in scale when comparing cylindrical and slit-shaped pores, one should use the diameter of a cylindrical pore (rather than its length) as its “pore-width” (J. Rouquerol et al., “Recommendations for the Characterization of Porous Solids”, Pure & Appl. Chem., Vol. 66, No. 8, pp. 1739-1758, 1994). The following distinctions and definitions were adopted in previous IUPAC documents (K. S. W. Sing, et al, Pure and Appl. Chem., vol. 57, n04, pp 603-919, 1985; and IUPAC “Manual on Catalyst Characterization”, J. Haber, Pure and Appl. Chem., vol. 63, pp. 1227-1246, 1991): micropores have widths (i.e. pore sizes) smaller than 2 nm; Mesopores have widths (i.e. pore sizes) of from 2 nm to 50 nm; and Macropores have widths (i.e. pore sizes) of greater than 50 nm. In addition, nanopores may be considered to have widths (i.e. pore sizes) of less than 1 nm.

Pores in a material may include “closed” pores as well as open pores. A closed pore is a pore in a material which is a non-connected cavity, i.e. a pore which is isolated within the material and not connected to any other pore and which cannot therefore be accessed by a fluid (e.g. a liquid, such as a solution) to which the material is exposed. An “open pore” on the other hand, would be accessible by such a fluid. The concepts of open and closed porosity are discussed in detail in J. Rouquerol et al., “Recommendations for the Characterization of Porous Solids”, Pure & Appl. Chem., Vol. 66, No. 8, pp. 1739-1758, 1994.

Open porosity therefore refers to the fraction of the total volume of the porous material in which fluid flow could effectively take place. It therefore excludes closed pores. The term “open porosity” is interchangeable with the terms “connected porosity” and “effective porosity”, and in the art is commonly reduced simply to “porosity”.

The term “without open porosity” as used herein therefore refers to a material with no effective open porosity. Thus, a material without open porosity typically has no macropores and no mesopores. A material without open porosity may comprise micropores and nanopores, however. Such micropores and nanopores are typically too small to have a negative effect on a material for which low porosity is desired.

The term “compact layer” as used herein refers to a layer without mesoporosity or macroporosity. A compact layer may sometimes have microporosity or nanoporosity.

The term “semiconductor device” as used herein refers to a device comprising a functional component which comprises a semiconductor material. This term may be understood to be synonymous with the term “semiconducting device”. Examples of semiconductor devices include a photovoltaic device, a solar cell, a photo detector, a photodiode, a photosensor, a chromogenic device, a transistor, a light-sensitive transistor, a phototransistor, a solid state triode, a battery, a battery electrode, a capacitor, a super-capacitor, a light-emitting device, a laser or a light-emitting diode. The term “optoelectronic device” as used herein refers to devices which source, control or detect light. Light is understood to include any electromagnetic radiation. Examples of optoelectronic devices include photovoltaic devices, photodiodes (including solar cells), phototransistors, photomultipliers, photoresistors, lasers and light emitting diodes.

The term “consisting essentially of” refers to a composition comprising the components of which it consists essentially as well as other components, provided that the other components do not materially affect the essential characteristics of the composition. Typically, a composition consisting essentially of certain components will comprise greater than or equal to 95 wt % of those components or greater than or equal to 99 wt % of those components.

Process for Producing a Passivated Semiconductor

The invention provides a process for producing a passivated semiconductor, which process comprises treating a semiconductor with a passivating agent, wherein: the semiconductor comprises a crystalline compound comprising: (i) one or more first cations (A); (ii) one or more metal cations (M); and (iii) one or more anions (X); and the passivating agent comprises a compound comprising an oxygen-oxygen single bond.

Passivation of a semiconductor is a process leading to the elimination or the decrease of the amount of surface and/or bulk defects responsible for unwanted recombination processes. A passivated semiconductor is a semiconductor in which defects on the surface or in the bulk of the semiconductor have been passivated. Typically, a passivated semiconductor is one in which surface defects have been passivated. Passivation may include passivation of vacancies or charge traps in the semiconductor. Passivation may include passivation by oxidation of neutral metal atoms in the semiconductor to metal cations. The passivation may accordingly be oxidative passivation. For instance, if the semiconductor prior to passivation comprises metal atoms (for instance with an oxidation state of zero), the passivated semiconductor may comprise oxidised metal ions in the form of metal oxides or metal hydroxides. For instance, passivation of a semiconductor, the formula of which comprises lead, typically leads to production of a passivated semiconductor which comprises lead oxide (i.e. a Pb═O bond) and/or lead hydroxide (i.e. a Pb—OH bond).

Whether or not a semiconductor has been passivated may be determined by comparing properties of the semiconductor before and after passivation. For instance, the extent of passivation may be determined by performing photoluminescence spectroscopy or x-ray photoemission spectroscopy.

The process comprises treating the semiconductor with the passivating agent. Treating includes contacting the semiconductor and the passivating agent, for instance where the passivating agent is contained in a liquid or gaseous composition which is allowed to contact the surface of the semiconductor. Treating involves bringing the semiconductor into contact with the passivating agent so that the semiconductor and passivating agent may interact. If trace amounts of the passivating agent are already present in contact with the semiconductor, this alone does not constitute treating the semiconductor with the passivating agent. Treating typically comprises externally applying the passivating agent to the semiconductor.

Passivating Agent The passivating agent comprises a compound comprising an oxygen-oxygen single bond. A compound comprising an oxygen-oxygen single bond is a compound, the structure of which includes an oxygen-oxygen single bond in one or more of its resonance structures. For instance, ozone (both the resonance structures of which includes an oxygen-oxygen single bond and an oxygen-oxygen double bond) is a compound comprising an oxygen-oxygen single bond. As used herein, oxygen (dioxygen, O₂) and oxygen plasma are not examples of compounds comprising an oxygen-oxygen single bond.

The passivating agent typically comprises: a compound comprising a peroxide group; a compound comprising a hydroperoxyl group; a compound comprising a perester group; a compound comprising a peranhydride group; a compound comprising a peracid group; or ozone (O₃). A peroxide group is a group of formula —O—O—. A hydroperoxyl group is a group of formula —O—O—H. A perester group is a group of formula —C(═O)—O—O—. A peracid group is a group of formula —C(═O)—O—O—H. A peranhydride group is a group of formula —C(═O)—O—O—C(═O)—. Typically, the compound comprises a peroxide group or a hydroperoxyl group.

The passivating agent may comprise: a compound of formula R—O—O—R; a compound of formula R—C(O)—O—O—R; or a compound of formula R—C(O)—O—O—C(O)—R, wherein: each R is independently selected from H, unsubstituted or substituted C₁₋₈ alkyl, unsubstituted or substituted C₁₋₈ alkenyl and unsubstituted or substituted aryl, optionally wherein each R is bound together to form a ring. Each group is typically unsubstituted or substituted with a group selected from halo, hydroxyl, nitro, C₁₋₃ alkyl or phenyl. R is typically H, C₁₋₆ alkyl, phenyl optionally substituted with one or more methyl groups, halo groups or nitro groups or benzyl optionally substituted with one or more methyl groups, halo groups or nitro groups. R may for instance be H, methyl, ethyl, isopropyl, tert-butyl, cumyl, phenyl or benzyl. R may in some instances be —SiR₃ where R is C₁₋₃ alkyl, phenyl or benzyl.

The passivating agent may be present as a single compound or may be complexed with a second compound. For instance, the passivating agent may be a compound comprising an oxygen-oxygen single bond which is complexed with urea.

The passivating agent typically comprises a compound selected from hydrogen peroxide, urea hydrogen peroxide, ozone, tert-butyl hydroperoxide, tert-butyl peroxybenzoate, di-tert-butyl peroxide, 2-butanone peroxide, cumene hydroperoxide, dicumyl peroxide, bis(trimethylsilyl) peroxide, benozyl peroxide, diacetyl peroxide, diethyl ether peroxide, dipropyl peroxydicarbonate, methyl ethyl ketone peroxide, peracetic acid, performic acid, peroxybenzoic acid and meta-chloroperoxybenzoic acid.

The passivating agent preferably comprises hydrogen peroxide or ozone. More preferably, the passivating agent comprises hydrogen peroxide. Thus, the invention provides a process for producing a passivated semiconductor which comprises treating the semiconductor with hydrogen peroxide.

The passivating agent may alternatively comprise an inorganic peroxide (for instance alkali metal or alkali earth metals such as barium peroxide, sodium peroxide, lithium peroxide, magnesium peroxide and calcium peroxide) or an inorganic ozonide (for instance potassium ozonide, rubidium ozonide or cesium ozonide).

The passivating agent may be present in a composition, which may be a solid composition, a liquid composition or a gaseous composition. For instance, the process may comprise treating the semiconductor with a composition comprising the passivating agent.

Semiconductor

The semiconductor comprises a crystalline compound comprising: (i) one or more first cations (A); (ii) one or more metal cations (M); and (iii) one or more anions (X). The semiconductor is accordingly typically an A/M/X compound.

A semiconductor is a compound with an electrical conductivity intermediate in magnitude between that of a conductor and a dielectric. A semiconductor may be a negative (n)-type semiconductor, a positive (p)-type semiconductor or an intrinsic (i) semiconductor. A semiconductor may have a band gap of from 0.5 to 3.5 eV, for instance from 0.5 to 2.5 eV or from 1.0 to 2.0 eV (when measured at 300 K).

The semiconductor typically comprises a photoactive material. The semiconductor may be a photoactive material.

The semiconductor comprises a crystalline compound, but may also comprise an amorphous material, for instance a polymer. The semiconductor typically comprises at least 50% by weight of the crystalline compound. The semiconductor may for instance comprise at least 80% by weight or at least 95% by weight of the crystalline compound. The semiconductor may consist essentially of the crystalline compound.

The semiconductor is typically in the form of a layer. The semiconductor may comprise a layer of the crystalline compound. The semiconductor may consist essentially of a layer comprising the crystalline compound.

The process may be a process for producing a layer of a passivating semiconductor, which process comprises treating a layer of the semiconductor with the passivating agent. Treating the layer of the semiconductor with the passivating agent may comprise disposing the passivating agent on the layer of the semiconductor.

The layer typically has a thickness of at least 50 nm or at least 100 nm. For instance, the semiconductor may comprise a layer comprising the crystalline compound which has a thickness of from 100 nm to 700 nm. The thickness of the layer may be measured by electron microscopy.

The crystalline compound may comprise a compound having the formula [A]ₐ[M]_{b}[X]_{c} wherein: [A] is the one or more first cations; [M] is one or more metal cations; [X] is the one or more anions; a is an integer from 1 to 3; b is an integer from 1 to 3; and c is an integer from 1 to 8. If [A] is one cation (A), [M] is two cations (M¹ and M²), and [X] is one anion (X), the crystalline material may comprise a compound of formula Aₐ(M¹,M²)_{b}X_{c}. [A] may represent one, two or more A ions. If [A], [M] or [X] is more than one ion, those ions may be present in any proportion. For instance, Aₐ(M¹,M²)_{b}X_{c} includes all compounds of formula AₐM¹_{by}M²_{b(1-y)}X_{c} wherein y is between 0.0 and 1.0, for instance from 0.05 to 0.95. Such materials may be referred to as mixed ion materials.

The one or more metal cations M may be one or more metal dications, one or more metal trications or one or more metal tetracations. The one or more first cations A are typically one or more monocations, for instance organic monocations and/or inorganic monocations. The one or more anions X are typically one or more halide anions (i.e. I⁻, Br⁻, Cl⁻ or F⁻,) or one or more chalcogenide anions (for instance O²⁻ or S²⁻).

The semiconductor preferably comprises a perovskite. Thus, typically the semiconductor comprises a crystalline compound of formula [A][M][X]₃, wherein: [A] comprises the one or more first cations; [M] comprises the one or more metal cations; and [X] comprises the one or more anions. The one or more anions typically comprise one or more halide anions selected from I⁻, Br⁻ and Cl⁻. [A] may comprise a single first cation and [M] may comprise a single metal cation. The crystalline compound may accordingly be a compound of formula AM[X]₃ which may, for instance, be a mixed halide perovskite. The perovskite is preferably a metal halide perovskite.

The perovskite may be an organic-inorganic perovskite wherein the one or more first cations (A) comprise an organic cation. The perovskite may alternatively be an all inorganic perovskite in which the one or more first cations are metal cations (for instance selected from K⁺, Rb⁺ and Cs⁺). As discussed above, the process of the invention is able to passivate both organic and inorganic perovskites.

The one or more first cations (A) are typically selected from K⁺, Rb⁺, Cs⁺, (NR¹R²R³R⁴)⁺, (R¹R²N═CR³R⁴)⁺, (R¹R²N—C(R⁵)═NR³R⁴)⁺ and (R¹R²N—C(NR⁵R⁶)═NR³R⁴)⁺, wherein each of R¹, R², R³, R⁴, R⁵ and R⁶ is independently H, unsubstituted or substituted C₁₋₂₀ alkyl or unsubstituted or substituted aryl. Each R¹, R², R³, R⁴, R⁵ and R⁶ is preferably selected from H and C₁₋₁₀ alkyl optionally substituted with phenyl. Each R¹, R², R³, R⁴, R⁵ and R⁶ may be H or methyl.

Preferably, the one or more first cations are selected from Cs⁺, (CH₃NH₃)⁺ and (H₂N—C(H)═NH₂)⁺. The one or more first cations preferably comprise Cs⁺ and (H₂N—C(H)═NH₂)⁺. The one or more first cations may alternatively be Cs⁺ as sole first cation or (CH₃NH₃)⁺ as sole first cation.

The one or more metal cations (M) are typically selected from Pb²⁺, Ca²⁺, Sr²⁺, Cd²⁺, Cu²⁺, Ni²⁺, Mn²⁺, Fe²⁺, Co²⁺, Pd²⁺, Ge²⁺, Sn²⁺, Yb²⁺, Eu²⁺, Bi³⁺, Sb³⁺, Pd⁴⁺, W⁴⁺, Re⁴⁺, Os⁴⁺, Ir⁴⁺, Pt⁴⁺, Sn⁴⁺, Pb⁴⁺, Ge⁴⁺ and Te⁴⁺.

Preferably, the crystalline compound comprises lead (Pb). For instance, the one or more metal cations may comprise Pb²⁺. The one or more metal cations may comprise Sn²⁺. For instance, the one or more metal cations may comprise Pb²⁺ and/or Sn²⁺.

The semiconductor may comprise a crystalline compound of formula [A]Pb_{z}Sn_{(1-z)}[X]₃, where z is from 0.0 to 1.0. When z is 0.0, the formula comprises only Sn²⁺ as the one or more metal cations. When z is 1.0, the formula comprises only Pb²⁺ as the one or more metal cations. z may for instance be from 0.1 to 0.9, in which case the crystalline compound is a mixed metal perovskite. In this formula, [A] typically comprises one or more of Cs⁺, (CH₃NH₃)⁺ and (H₂N—C(H)═NH₂)⁺ and [X] typically comprises one or more of I⁻, Br⁻ and Cl⁻.

The crystalline compound may for instance comprise: a perovskite compound of formula CH₃NH₃PbI₃, CH₃NH₃PbBr₃, CH₃NH₃PbCl₃, CH₃NH₃PbF₃, CH₃NH₃PbBr_{3y}I_{3(1-y)}, CH₃NH₃PbBr_{3y}Cl_{3(1-y)}, CH₃NH₃PbI_{3y}Cl_{3(1-y)}, CH₃NH₃PbI_{3(1-y)}Cl_{3y}, CH₃NH₃SnI₃, CH₃NH₃SnBr₃, CH₃NH₃SnCl₃, CH₃NH₃SnF₃, CH₃NH₃SnBrI₂, CH₃NH₃SnBr_{3y}I_{3(1-y)}, CH₃NH₃SnBr_{3y}Cl_{3(1-y)}, CH₃NH₃SnF_{3(1-y)}Br_{3y}, CH₃NH₃SnI_{3y}Br_{3(1-y)}, CH₃NH₃SnI_{3y}Cl_{3(1-y)}, CH₃NH₃SnF_{3(1-y)}I_{3y}, CH₃NH₃SnCl_{3y}Br_{3(1-y)}, CH₃NH₃SnI_{3(1-y)}Cl_{3y} and CH₃NH₃SnF_{3(1-y)}Cl_{3y}, CH₃NH₃CuI₃, CH₃NH₃CuBr₃, CH₃NH₃CuCl₃, CH₃NH₃CuF₃, CH₃NH₃CuBrI₂, CH₃NH₃CuBr_{3y}I_{3(1-y)}, CH₃NH₃CuBr_{3y}Cl_{3(1-y)}, CH₃NH₃CuF_{3(1-y)} Br_{3y}, CH₃NH₃CuI_{3y}Br_{3(1-y)}, CH₃NH₃CuI_{3y}Cl_{3(1-y)}, CH₃NH₃CuF_{3(1-y)}I_{3y}, CH₃NH₃CuCl_{3y}Br_{3(1-y)}, CH₃NH₃CuI_{3(1-y)}Cl_{3y}, or CH₃NH₃CuF_{3(1-y)}Cl_{3y} where y is from 0 to 1; a perovskite compound of formula (H₂N—C(H)═NH₂)PbI₃, (H₂N—C(H)═NH₂)PbBr₃, (H₂N—C(H)═NH₂)PbCl₃, (H₂N—C(H)═NH₂)PbF₃, (H₂N—C(H)═NH₂)PbBr_{3y}I_{3(1-y)} (H₂N—C(H)═NH₂)PbBr_{3y}Cl_{3(1-y)}, (H₂N—C(H)═NH₂)PbI_{3y}Br_{3(1 y)}, (H₂N—C(H)═NH₂)PbI_{3y}Cl_{3(1-y)}, (H₂N—C(H)═NH₂)PbCl_{3y}Br_{3(1-y)}, (H₂N—C(H)═NH₂)PbI_{3(1-y)}Cl_{3y}, (H₂N—C(H)═NH₂)SnI₃, (H₂N—C(H)═NH₂)SnBr₃, (H₂N—C(H)═NH₂)SnCl₃, (H₂N—C(H)═NH₂)SnF₃, (H₂N—C(H)═NH₂)SnBrI₂, (H₂N—C(H)═NH₂)SnBr_{3y}I_{3(1-y)}, (H₂N—C(H)═NH₂)SnBr_{3y}Cl_{3(1-y)}, (H₂N—C(H)═NH₂)SnF_{3(1-y)} Br_{3y}, (H₂N—C(H)═NH₂)SnI_{3y}Br_{3(1-y)}, (H₂N—C(H)═NH₂)SnI_{3y}Cl_{3(1-y)}, (H₂N—C(H)═NH₂)SnF_{3(1-y)}I_{3y}, (H₂N—C(H)═NH₂)SnCl_{3y}Br_{3(1-y)}, (H₂N—C(H)═NH₂)SnI_{3(1-y)}Cl_{3y}, (H₂N—C(H)═NH₂)SnF_{3(1-y)}Cl_{3y}, (H₂N—C(H)═NH₂)CuI₃, (H₂N—C(H)═NH₂)CuBr₃, (H₂N—C(H)═NH₂)CuCl₃, (H₂N—C(H)═NH₂)CuF₃, (H₂N—C(H)═NH₂)CuBrI₂, (H₂N—C(H)═NH₂)CuBr_{3y}I_{3(1-y)}, (H₂N—C(H)═NH₂)CuBr_{3y}Cl_{3(1-y)}, (H₂N—C(H)═NH₂)CuF_{3(1-y)} Br_{3y}, (H₂N—C(H)═NH₂)CuI_{3y}Br_{3(1-y)}, (H₂N—C(H)═NH₂)CuI_{3y}Cl_{3(1-y)}, (H₂N—C(H)═NH₂)CuF_{3(1-y)}I_{3y}, (H₂N—C(H)═NH₂)CuCl_{3y}Br_{3(1-y)}, (H₂N—C(H)═NH₂)CuI_{3(1-y)}Cl_{3y}, or (H₂N—C(H)═NH₂)CuF_{3(1-y)}Cl_{3y} where y is from 0 to 1; or a perovskite compound of formula (H₂N—C(H)═NH₂)ₓCs₁₋ₓPbI₃, (H₂N—C(H)═NH₂)ₓCs₁₋ₓPbBr₃, (H₂N—C(H)═NH₂)ₓCs₁₋ₓPbCl₃, (H₂N—C(H)═NH₂)ₓCs₁₋ₓPbF₃, (H₂N—C(H)═NH₂)ₓCs₁₋ₓPbBr_{3y}I_{3(1-y)}, (H₂N—C(H)═NH₂)ₓCs₁₋ₓPbBr_{3y}Cl_{3(1-y)}, (H₂N—C(H)═NH₂)ₓCs₁₋ₓPbI_{3y}Br_{3(1-y)}, (H₂N—C(H)═NH₂)ₓCs₁₋ₓPbI_{3y}Cl_{3(1-y)}, (H₂N—C(H)═NH₂)ₓCs₁₋ₓPbCl_{3y}Br_{3(1-y)}, (H₂N—C(H)═NH₂)ₓCs₁₋ₓPbI_{3(1-y)}, Cl_{3y}, (H₂N—C(H)═NH₂)ₓCs₁₋ₓSnI₃, (H₂N—C(H)═NH₂)ₓCs₁₋ₓSnBr₃, (H₂N—C(H)═NH₂)ₓCs₁₋ₓSnCl₃, (H₂N—C(H)═NH₂)ₓCs₁₋ₓSnF₃, (H₂N—C(H)═NH₂)ₓCs₁₋ₓSnBrI₂, (H₂N—C(H)═NH₂)ₓCs₁₋ₓSnBr_{3y}I_{3(1-y)}, (H₂N—C(H)═NH₂)ₓCs₁₋ₓSnBr_{3y}Cl_{3(1-y)}, (H₂N—C(H)═NH₂)ₓCs₁₋ₓSnF_{3(1-y)}Br_{3y}, (H₂N—C(H)═NH₂)ₓCs₁₋ₓSnI_{3y}Br_{3(1-y)}, (H₂N—C(H)═NH₂)ₓCs₁₋ₓSnI_{3y}Cl_{3(1-y)}, (H₂N—C(H)═NH₂)ₓCs₁₋ₓSnF_{3(1-y)}I_{3y}, (H₂N—C(H)═NH₂)ₓCs₁₋ₓSnCl_{3y}Br_{3(1-y)}, (H₂N—C(H)═NH₂)ₓCs₁₋ₓSnI_{3(1-y)}Cl_{3y}, (H₂N—C(H)═NH₂)ₓCs₁₋ₓSnF_{3(1-y)}Cl_{3y}, (H₂N—C(H)═NH₂)ₓCs₁₋ₓCuI₃, (H₂N—C(H)═NH₂)ₓCs₁₋ₓCuBr₃, (H₂N—C(H)═NH₂)ₓCs₁₋ₓCuCl₃, (H₂N—C(H)═NH₂)ₓCs₁₋ₓCuF₃, (H₂N—C(H)═NH₂)ₓCs₁₋ₓCuBrI₂, (H₂N—C(H)═NH₂)ₓCs₁₋ₓCuBr_{3y}I_{3(1-y)}, (H₂N—C(H)═NH₂)ₓCs₁₋ₓCuBr_{3y}Cl_{3(1-y)}, (H₂N—C(H)═NH₂)ₓCs₁₋ₓCuF_{3(1-y)}Br_{3y}, (H₂N—C(H)═NH₂)ₓCs₁₋ₓCuI_{3y}Br_{3(1-y)}, (H₂N—C(H)═NH₂)ₓCs₁₋ₓCuI_{3y}Cl_{3(1-y)}, (H₂N—C(H)═NH₂)ₓCs₁₋ₓCuF_{3(1-y)}I_{3y}, (H₂N—C(H)═NH₂)ₓCs₁₋ₓCuCl_{3y}Br_{3(1-y)}, (H₂N—C(H)═NH₂)ₓCs₁₋ₓCuI_{3(1-y)}Cl_{3y}, or (H₂N—C(H)═NH₂)ₓCs₁₋ₓCuF_{3(1-y)}Cl_{3y} where x is from 0 to 1 and y is from 0 to 1. x may for instance be from 0.05 to 0.95. y may for instance be from 0.05 to 0.95.

Preferably, the semiconductor comprises CH₃NH₃PbBr_{3y}I_{3(1-y)}, CsPbBr_{3y}I_{3(1-y)} or Csₓ(H₂N—C(H)═NH₂)₍₁₋ₓ₎PbBr_{3y}I_{3(1-y)}, where x is from 0.0 to 1.0 and y is from 0.0 to 1.0. For instance, the semiconductor may comprise CH₃NH₃PbI₃, CsPbBr_{3y}I_{3(1-y)} or Csₓ(H₂N—C(H)═NH₂)₍₁₋ₓ₎PbBr₃I_{3(1-y)}, where x is from 0.05 to 0.95 and y is from 0.05 to 0.95.

Preferably, the semiconductor comprises a crystalline compound of formula Csₓ(H₂N—C(H)═NH₂)₍₁₋ₓ₎PbBr_{3y}I_{3(1-y)}, where x is from 0.0 to 1.0 and y is from 0.0 to 1.0. Typically, x is from 0.05 to 0.50 or from 0.10 to 0.30. x may for instance be from 0.15 to 0.20. Typically, y is from 0.01 to 0.70 or from 0.20 to 0.60. y may for instance be from 0.30 to 0.50. The crystalline compound is preferably Cs_{0.2}(H₂N—C(H)═NH₂)_{0.8}Pb(Br_{0.4}I_{0.6})₃ or Cs_{0.17}(H₂N—C(H)═NH₂)_{0.83}Pb(Br_{0.4}I_{0.6})₃.

The semiconductor may alternatively comprise a hexahalometallate of formula [A]₂[M][X]₆ wherein: [A] is the one or more first cations; [M] is the one or more metal cations; and [X] is the one or more anions. For instance, the hexahalometallate compound may be Cs₂MI₆, Cs₂MBr₆, Cs₂MBr_{6-y}I_{y}, Cs₂MCl_{6-y}I_{y}, Cs₂MCl_{6-y}Br_{y}, (CH₃NH₃)₂MI₆, (CH₃NH₃)₂MBr₆, (CH₃NH₃)₂MBr_{6-y}I_{y}, (CH₃NH₃)₂MCl_{6-y}I_{y}, (CH₃NH₃)₂MCl_{6-y}Br_{y}, (H₂N—C(H)═NH₂)₂MI₆, (H₂N—C(H)═NH₂)₂MBr₆, (H₂N—C(H)═NH₂)₂MBr_{6-y}I_{y}, (H₂N—C(H)═NH₂)₂MCl_{6-y}I_{y} or (H₂N—C(H)═NH₂)₂MCl_{6-y}Br_{y} wherein y is from 0.01 to 5.99 and M is Sn²⁺ or Pb²⁺.

The semiconductor may alternatively comprise a double perovskite compound of formula of formula [A]₂[B^{I}][B^{III}][X]₆ wherein: [A] is the one or more first cations; [B^{I}] is one or more metal monocations; [B^{III}] is one or more metal trications; and [X] is the one or more anions. [B^{I}] may be selected from Li⁺, Na⁺, K⁺, Rb⁺, Cs⁺, Cu⁺, Ag⁺, Au⁺ and Hg⁺, preferably from Cu⁺, Ag⁺ and Au⁺. [B^{III}] may be selected from Bi³⁺, Sb³⁺, Cr³⁺, Fe³⁺, Co³⁺, Ga³⁺, As³⁺, Ru³⁺, Rh³⁺, In³⁺, Ir³⁺ and Au³⁺, preferably from Bi³⁺ and Sb³⁺. The double perovskite may be a compound of formula Cs₂AgBiX₆, (H₂N—C(H)═NH₂)₂AgBiX₆, (H₂N—C(H)═NH₂)₂AuBiX₆, (CH₃NH₃)₂AgBiX₆ or (CH₃NH₃)₂AuBiX₆ where X is I⁻, Br⁻ or Cl⁻. The double perovskite may be a compound of formula Cs₂AgBiBr₆.

Process Conditions

The process is typically conducted at a temperature of less than 100° C. For instance, the semiconductor may be treated with the passivating agent at a temperature of from 10° C. to 90° C. The process may be conducted at room temperature. For instance, the semiconductor may be treated with the passivating agent at a temperature from 15° C. to 35° C.

The semiconductor is typically treated by contacting the semiconductor with a composition comprising the passivating agent, which composition is a liquid composition or a gaseous composition. The composition typically comprises at least 0.001 mol % of the passivating agent relative to the amount of the crystalline compound present in the semiconductor. For instance, the composition may comprise a total amount of at least 0.00001 mole of the passivating agent for each 1 mole of the semiconductor which is contacted with the composition. The composition may for instance comprise a total amount of at least 0.0001 mole of the passivating agent for each 1 mole of the semiconductor which is contacted with the composition.

If the composition is a liquid composition, the concentration of the passivating agent in the liquid composition is typically at least 0.001 M, for instance from 0.001 M to 1.0 M. The concentration of the passivating agent is typically from 0.001 M to 0.1 M. The liquid composition usually comprises a solvent and the passivating agent. The passivating agent is typically dissolved in the solvent.

Treating the semiconductor with the passivating agent typically comprises exposing the semiconductor to a composition comprising a solvent and the passivating agent. The composition comprising the solvent and the passivating agent preferably comprises a solution of the passivating agent in the solvent. The solution may be an aqueous solution. An aqueous solution is a solution in which water is present.

The solvent may be any suitable solvent, for one in which the passivating agent is soluble. Each solvent may be a polar solvent or a non-polar solvent. The solvent in the liquid composition typically comprises one or more polar solvents. The solvent typically comprises one or more of water, an alcohol (for instance methanol, ethanol, isopropanol or 2-ethoxyethanol), a ketone (for instance acetone or methyl ethyl ketone), a nitrile (for instance acetonitrile), a chlorohydrocarbon (for instance dichloromethane, chlorobenzene or chloroform), an ether (for instance dimethyl ether or tetrahydrofuran), a sulfoxide (for instance dimethylsulfoxide) or an amide (for instance dimethylformamide). The solvent typically comprises water and/or an alcohol. The solvent may comprise water and methanol, ethanol or isopropanol. Preferably, the solvent comprises water and isopropanol.

The semiconductor may be treated with the liquid composition comprising the passivating agent by disposing the liquid composition on the semiconductor. For instance, the semiconductor may be dipped in the liquid composition or the liquid composition may be spin-coated or sprayed onto the semiconductor. The process may comprise dipping a layer of the semiconductor disposed on a substrate into a liquid composition comprising the passivating agent. The process may comprise spin-coating or spraying a liquid composition comprising the passivating agent onto a layer of the semiconductor disposed on a substrate.

Preferably, treating the semiconductor with the passivating agent comprises exposing the semiconductor to an aqueous solution of hydrogen peroxide. The aqueous solution may be a solution of hydrogen peroxide in water and isopropanol. Preferably, the aqueous solution of hydrogen peroxide comprises hydrogen peroxide at a concentration of from 0.0001 to 0.5 M or from 0.001 to 0.1 M, for instance from 0.005 to 0.05 M.

The composition may be an aqueous solution of ozone. The composition may accordingly comprise water and ozone.

The semiconductor is typically contacted with the liquid composition for from 0.1 to 100 seconds. For instance, the semiconductor may be contacted with the liquid composition for from 0.5 to 10 seconds.

After treatment of the semiconductor with a composition comprising a solvent and the passivating agent, the passivated semiconductor may be dried to remove any remaining solvent. Drying may comprise exposing the passivated semiconductor to compressed air or heating the passivated semiconductor, for instance at a temperature from 30° C. to 150° C., optionally for from 30 seconds to 30 minutes.

The process may comprise treating the semiconductor with the passivating agent by exposing the semiconductor to a vapour comprising the passivating agent. The composition comprising the passivating agent may accordingly be a gaseous composition.

The semiconductor may be treated with a (gaseous) composition comprising at least 5% by volume of the passivating agent in a gaseous or vapour form. For instance, the partial pressure of the passivating agent in the gaseous composition may be at least 5% of the total pressure of the gaseous composition. The composition may comprise at least 10% by volume of the passivating agent, at least 20% by volume of the passivating agent or at least 30% by volume of the passivating agent. The partial pressure of the passivating agent in the gaseous composition may be at least 10% of the total pressure of the gaseous composition, at least 20% of the total pressure of the gaseous composition or at least 30% of the total pressure of the gaseous composition.

The semiconductor may be treated with a gaseous composition comprising the passivating agent at low pressure (for instance under vacuum) or at a higher pressure (for instance at around atmospheric pressure). Accordingly, the semiconductor may be exposed to a vapour comprising the comprising the passivating agent in a chamber, where the pressure in the chamber is less than 1.0 Pa, for instance less than 10⁻³ Pa, (vacuum deposition) or where the pressure in the chamber is from 100 Pa to 10⁶ Pa (i.e. from approximately 0.01 to 10 atmospheres).

Typically, the semiconductor is exposed to a vapour comprising the comprising the passivating agent in a chamber at a pressure of from 50000 to 150000 Pa (approximately from 0.5 to 1.5 atmospheres). For instance, the process may comprise placing the semiconductor in an enclosed chamber with a source of the passivating agent and heating the source of the passivating agent to produce a vapour comprising the passivating agent.

Treating the semiconductor with the passivating agent may comprise exposing the semiconductor to a vapour comprising hydrogen peroxide. Preferably, the process further comprises generating the vapour comprising hydrogen peroxide by heating a composition comprising urea hydrogen peroxide. Urea hydrogen peroxide liberates hydrogen peroxide on heating.

Treating the semiconductor with the passivating agent may comprise exposing the semiconductor to ozone gas. For instance, the substrate may be placed in a chamber comprising an atmosphere of ozone. The amount of ozone present may be from 10% to 50%, or from 20% to 40%, of the atmosphere by volume (for instance a partial pressure of from 10% to 50% of the total pressure in the chamber). The gaseous composition comprising ozone may further comprise oxygen.

The process may further comprise an annealing step following treatment of the semiconductor by the passivating agent. For instance, the passivated semiconductor may be heated at a temperature of from 30° C. to 150° C., optionally for from 30 seconds to 30 minutes.

Alternatively, the process optionally does not further comprise an annealing step following treatment of the semiconductor by the passivating agent.

An advantage of the invention is that it does not require illumination (for instance light soaking) in order to achieve passivation. While the process may be performed in either light or dark conditions, it may be performed without intense illumination. For instance, passivation may occur under ambient light conditions in the interior of a building. The passivating may occur at illumination intensities of less than that of typical solar illumination, for instance less than 100 mW/cm² (for instance less than 50 mW/cm²). Thus, the semiconductor may be illuminated with an intensity of no greater than 0.5 kW/m² during treatment with the passivating agent. Optionally, the semiconductor may illuminated with an intensity of no greater than 0.1 kW/m² during treatment with the passivating agent, or no greater than 0.01 kW/m² during treatment with the passivating agent. The process may be conducted in the substantial absence of illumination or light.

The process of the invention allows the semiconductor to be passivated quickly. Whereas a process such as photo-brightening may take several hours, the process according to the invention allows for a passivated semiconductor to be produced in seconds or minutes. Accordingly, the semiconductor is typically treated with the passivating agent for less than 1 hour. Optionally, the semiconductor is treated with the passivating agent for less than 1 minute.

Passivation of the semiconductor may cause a number of improvements for the optical properties of the semiconductor. The passivated semiconductor typically has an increased photoluminescence lifetime and/or an increased photoluminescence intensity compared with the semiconductor before passivation.

Substrate

The semiconductor may be in the form of a layer comprising the crystalline compound disposed on a substrate. The substrate typically comprises a layer of a first electrode material. The first electrode material may comprise a metal (for instance silver, gold, aluminium or tungsten) or a transparent conducting oxide (for instance fluorine doped tin oxide (FTO) or indium tin oxide (ITO)). Typically, the first electrode comprises a transparent conducting oxide.

The substrate may, for instance, comprise a layer of a first electrode material and a layer of an n-type semiconductor. Often, the substrate comprises a layer of a transparent conducting oxide, for instance FTO, and a compact layer of an n-type semiconductor, for instance TiO₂ or SnO₂.

In some embodiments, the substrate comprises a layer of a porous scaffold material. The layer of a porous scaffold is usually in contact with a layer of an n-type or p-type semiconductor material, for instance a compact layer of an n-type semiconductor or a compact layer of a p-type semiconductor. The scaffold material is typically mesoporous or macroporous. The scaffold material may aid charge transport from the crystalline material to an adjacent region. The scaffold material may also aid formation of the layer of the crystalline material during deposition. The porous scaffold material is typically infiltrated by the crystalline material after deposition.

Typically, the porous scaffold material comprises a dielectric material or a charge-transporting material. The scaffold material may be a dielectric scaffold material. The scaffold material may be a charge-transporting scaffold material. The porous scaffold material may be an electron-transporting material or a hole-transporting scaffold material. n-type semiconductors are examples of electron-transporting materials. p-type semiconductors are examples of hole-transporting scaffold materials. Preferably, the porous scaffold material is a dielectric scaffold material or an electron-transporting scaffold material (e.g. an n-type scaffold material).

The porous scaffold material may be a charge-transporting scaffold material (e.g. an electron-transporting material such as titania, or alternatively a hole transporting material) or a dielectric material, such as alumina. The term “dielectric material”, as used herein, refers to material which is an electrical insulator or a very poor conductor of electric current. The term dielectric therefore excludes semiconducting materials such as titania. The term dielectric, as used herein, typically refers to materials having a band gap of equal to or greater than 4.0 eV. (The band gap of titania is about 3.2 eV.) The skilled person of course is readily able to measure the band gap of a material by using well-known procedures which do not require undue experimentation. For instance, the band gap of a material can be estimated by constructing a photovoltaic diode or solar cell from the material and determining the photovoltaic action spectrum. The monochromatic photon energy at which the photocurrent starts to be generated by the diode can be taken as the band gap of the material; such a method was used by Barkhouse et al., Prog. Photovolt: Res. Appl. 2012; 20:6-11. References herein to the band gap of a material mean the band gap as measured by this method, i.e. the band gap as determined by recording the photovoltaic action spectrum of a photovoltaic diode or solar cell constructed from the material and observing the monochromatic photon energy at which significant photocurrent starts to be generated.

The thickness of the layer of the porous scaffold is typically from 5 nm to 400 nm. For instance, the thickness of the layer of the porous scaffold may be from 10 nm to 50 nm.

The substrate may, for instance, comprise a layer of a first electrode material, a layer of an n-type semiconductor, and a layer of a dielectric scaffold material. The substrate may therefore comprise a layer of a transparent conducting oxide, a compact layer of TiO₂ and a porous layer of Al₂O₃.

Often, the substrate comprises a layer of a first electrode material and a layer of an n-type semiconductor or a layer of a p-type semiconductor.

Typically, the substrate comprises a layer of a first electrode material and optionally one or more additional layers that are each selected from: a layer of an n-type semiconductor, a layer of a p-type semiconductor, and a layer of insulating material. Typically, a surface of the substrate on which the precursor composition is disposed comprises one or more of a first electrode material, a layer of an n-type semiconductor, a layer of a p-type semiconductor, and a layer of insulating material.

Process for Producing a Device

The invention provides a process for producing a semiconductor device, wherein the process comprises producing a passivated semiconductor by a method according to any one of the preceding claims.

The process typically further comprises disposing on the passivated semiconductor (which may be in the form of a layer) a layer of a p-type semiconductor or a layer of a n-type semiconductor. Often, the process typically comprises disposing on the passivated semiconductor a layer of a p-type semiconductor. The n-type or p-type semiconductor may be an organic p-type semiconductor. Suitable p-type semiconductors may be selected from polymeric or molecular hole transporters. Preferably, the p-type semiconductor is spiro-OMeTAD. The layer of a p-type semiconductor or a layer of a n-type semiconductor is typically disposed on the passivated semiconductor by solution-processing, for instance by disposing a composition comprising a solvent and the n-type or p-type semiconductor. The solvent may be selected from polar solvents, for instance chlorobenzene or acetonitrile. The thickness of the layer of the p-type semiconductor or the layer of the n-type semiconductor is typically from 50 nm to 500 nm.

The process typically further comprises disposing on the layer of the p-type semiconductor or n-type semiconductor a layer of a second electrode material. The second electrode material may be as defined above for the first electrode material. Typically, the second electrode material comprises, or consists essentially of, a metal. Examples of metals which the second electrode material may comprise, or consist essentially of, include silver, gold, copper, aluminium, platinum, palladium, or tungsten. The second electrode may be disposed by vacuum evaporation. The thickness of the layer of a second electrode material is typically from 5 nm to 100 nm.

Typically, the semiconductor device is an optoelectronic device, a photovoltaic device, a solar cell, a photo detector, a photodiode, a photosensor (photodetector), a radiation detector, a chromogenic device, a transistor, a diode, a light-sensitive transistor, a phototransistor, a solid state triode, a battery, a battery electrode, a capacitor, a super-capacitor, a light-emitting device, a light-emitting diode or a laser.

The semiconductor device is typically an optoelectronic device. Examples of optoelectronic devices include photovoltaic devices, photodiodes (including solar cells), phototransistors, photomultipliers, photoresistors, and light emitting devices. Preferably, the semiconductor device is a photovoltaic device or a light emitting device.

Composition

The invention also provides a composition comprising: (i) the semiconductor; and (ii) the passivating agent, wherein the concentration of the passivating agent is greater than or equal to 0.001 mol % relative to the amount of the semiconductor. The concentration of the passivating agent is typically greater than or equal to 0.01 mol % relative to the amount of the semiconductor or greater than or equal to 1.0 mol % relative to the amount of the semiconductor. For instance, for each mole of semiconductor present there may be from 0.0001 mole to 0.5 mole of the passivating agent, for instance from 0.001 mole to 0.1 mole of the passivating agent.

The composition may comprise the semiconductor in an amount of from 50% to 99.9% by weight relative to the total composition and the passivating agent in an amount of from 0.001% to 20% by weight relative to the weight of the total composition.

For instance, the composition may be a composition comprising the semiconductor in solid form (or the semiconductor dissolved in a solvent) and, for each mole of semiconductor present, at least 0.001 mole of the passivating agent in solid, liquid or gaseous form. If the semiconductor and the passivating agent are both present in solid form, then the composition comprises the combined solid forms of the semiconductor and the passivating agent. If the semiconductor is present in a solid form and the passivating agent is present in liquid form (for instance dissolved in a solvent), then the composition comprises the combined solid semiconductor and the liquid form of the passivating agent, for instance as a layer of the semiconductor with a solution of the passivating agent disposed thereon. If the semiconductor is present in a solid form and the passivating agent is present in gaseous form (for instance as a vapour), the composition comprises the combined solid semiconductor and the gaseous passivating agent, for instance wherein the composition is defined by a container comprising the solid semiconductor and the gaseous passivating agent.

The semiconductor is typically a perovskite. The passivating agent is typically a peroxide compound. The passivating agent is preferably hydrogen peroxide or ozone. The passivating agent is more preferably hydrogen peroxide. Thus, the composition may comprise a semiconductor which is a perovskite and a passivating agent which comprises hydrogen peroxide.

The composition may further comprise a solvent as defined herein. For instance, the composition may comprise the semiconductor in solid form and a solution of the passivating agent. The composition may comprise a perovskite and an aqueous solution of hydrogen peroxide. The composition may comprise a perovskite, hydrogen peroxide, water and an alcohol (for instance isopropanol).

Use

The invention provides the use of a composition comprising a passivating agent for passivating a semiconductor, wherein: the semiconductor comprises a crystalline compound comprising: (i) one or more first cations (A); (ii) one or more metal cations (M); and (iii) one or more anions (X); and the passivating agent comprises a compound comprising an oxygen-oxygen single bond.

The inventors have found that certain oxygen-containing passivating agents may passivate a semiconductor comprising a crystalline compound without requiring the additional complication of illumination. The invention accordingly also provides the use of a composition comprising a passivating agent for passivating a semiconductor which is illuminated with an intensity of no greater than 0.5 kW/m² during passivation, wherein: the semiconductor comprises a crystalline compound comprising: (i) one or more first cations (A); (ii) one or more metal cations (M); and (iii) one or more anions (X); and the passivating agent comprises a compound comprising an oxygen-oxygen single bond or an oxygen-oxygen double bond. The semiconductor may be illuminated with an intensity of no greater than 0.1 kW/m² during passivation, or no greater than 0.01 kW/m² during treatment with the passivating agent. The use may be conducted in the substantial absence of illumination or light.

The passivating agent may comprises oxygen plasma or a compound comprising an oxygen-oxygen single bond as defined herein. For instance, the passivating agent may comprise oxygen plasma, hydrogen peroxide or ozone. The use according to the invention may be as further defined for the process of the invention herein.

Embodiments of the invention are described in more detail by reference to the following Examples.

### EXAMPLES

Materials and Methods

FA_{0.83}Cs_{0.17}Pb(I_{0.83}Br_{0.17})₃Perovskite Thin Films

FA_{0.83}Cs_{0.17}Pb(I_{0.83}Br_{0.17})₃ solutions were made with a 4:1 volume ratio DMF:DMSO (dimethyl formamide:dimethyl sulfoxide) and adding the following precursor salts to obtain a stoichiometric solution in the desired composition: formamidinium iodide (FAI) (GreatCell Solar), caesium iodide (CsI) (99.9%, Alfa Aesar), lead iodide PbI₂ (99%, Sigma-Aldrich), lead bromide (PbBr₂) (98%, Alfa Aesar). Solutions were prepared on the same day as they were deposited. Films of perovskite were obtained by spin-coating in a two-step process; first at 1000 rpm for 10 s then at 6000 rpm for 35 s, acceleration of 2000 rpm/s. A solvent quench with anisole was performed 10 s before the end of the spinning process. Spectroscopy samples were fabricated on glass following a cleaning procedure consisting of a series of sonication steps; first in Hellmanex (5% in deionised water), followed by neat deionised water then acetone and finally isopropanol. Substrates were then treated in a Model 42 Series UVO-Cleaner from Jelight Company for 10 minutes. Alternatively, substrates were exposed to O₂ plasma (Pico, Diener electronic) for 10 minutes.

All Inorganic Perovskite CsPb(Br_{0.9}I_{0.1})₃ Thin Films

CsPb(I_{0.1}Br_{0.9})₃ solutions were made in DMSO with a 0.5 M concentration using the following precursor salts: caesium iodide (CsI) (99.9%, Alfa Aesar), lead iodide PbI₂ (99%, Sigma-Aldrich), lead bromide (PbBr₂) (98%, Alfa Aesar) and caesium bromide (99.9%, Alfa Aesar). Solutions were prepared and stirred at room temperature 24 h prior to spin-coating. Films of perovskite were obtained by spin-coating on cleaned glass, in dry air, in a two-step process; first at 4000 rpm for 40 s, acceleration of 1000 rpm/s, then at 6000 rpm for 5 s, acceleration of 2000 rpm/s. A solvent quench with anisole was performed 8 s before the end of the spinning process. The resulting films were then annealed at 150° C. for 15 minutes.

Hydrogen Peroxide Treatment

For the wet-deposition method, hydrogen peroxide solution (30 wt % in water, Sigma-Aldrich) was diluted in iso-propanol (IPA). Two beakers were prepared, one containing hydrogen peroxide diluted to various concentrations in 10 mL of IPA and a second beaker containing 80 mL of IPA. Substrates were dipped in the first beaker for 1 s and then washed in the second beaker for 2 s. They were then dried with a compressed air gun to remove any remaining solution.

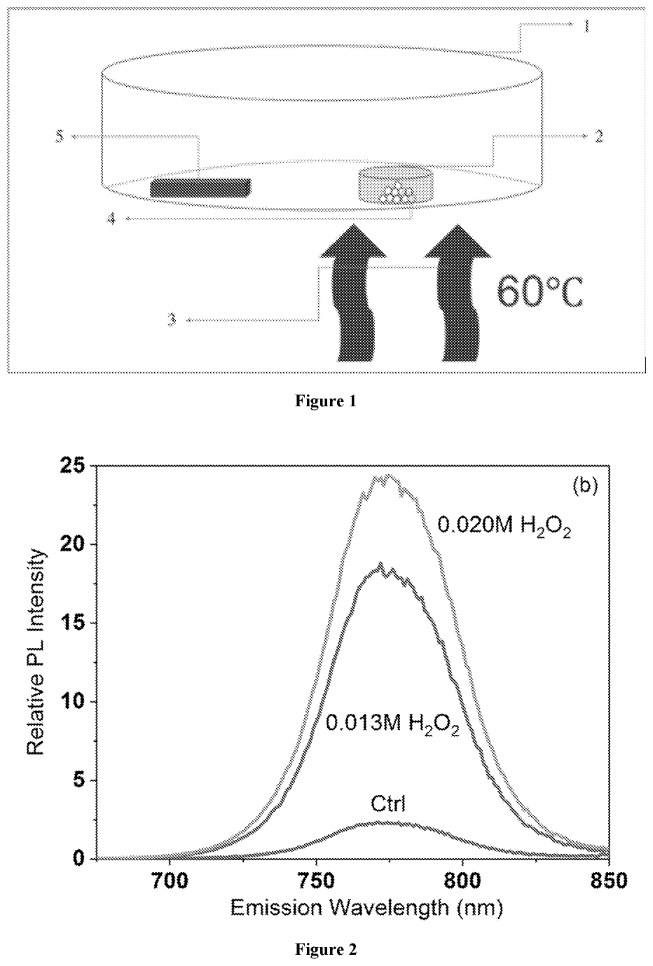

For the gas-deposition method of hydrogen peroxide, 100 mg of urea hydrogen peroxide adduct (>97%, Sigma Aldrich) was placed in a large, covered Petri dish to create a closed gas chamber which was heated to 60° C. with the perovskite substrate and left for various time intervals. Between 0° C. and 90° C., hydrogen peroxide leaves the adduct as a pure gas, leaving behind urea. The higher the temperature the faster the release of hydrogen peroxide and the greater the concentration that will be present in the chamber. Above 90° C., urea starts to decompose from the adduct giving unwanted side reactants. The decomposition products of hydrogen peroxide are oxygen and water. Oxygen, water and urea are identified as non-hazardous materials according to safety and handling regulations therefore, at the operating temperature of 60° C., the final products of this treatment are completely non-toxic. The gas deposition method is summarised in FIG. 1.

Oxygen Plasma Treatment

A low-pressure plasma system (Pico, Diener Electronic) was used for the oxygen plasma post-treatment on the perovskite. Substrates were pumped to vacuum for 5 minutes, then filled with oxygen for another 5 minutes and finally plasma was generated and held for various times for post-treatment of the perovskite light-absorbing layer.

Ozone Treatment

An ozone generator (Ulsonix) supplied a gas flow of 30% ozone in oxygen which substrates were exposed to for varying time intervals.

X-Ray and Ultra-Violet Photoemission Spectroscopy (XPS UPS)

A Thermo Scientific Kα X-Ray Photoelectron spectrometer was used to perform XPS measurements using a monochromated Al Kα X-Ray source at a take-off angle of 90°. The core level XPS spectra were recorded using a pass energy of 20 eV (resolution approximately 0.4 eV) from an analysis area of 300 m×300 m. The spectrometer work function and binding energy scale were calibrated using the Fermi edge and 3d peak recorded from a polycrystalline silver (Ag) sample prior to the commencement of the experiments. Fitting procedures to extract peak positions and relative stoichiometry from the XPS data were carried out using the Avantage XPS software suite.

Steady State and Time-Resolved Photoluminescence (PL)

Time-resolved PL measurements were acquired using a time-correlated single photon counting (TCSPC) setup (FluoTime 300, PicoQuant GmbH). Film samples were photoexcited using a 507 nm laser head (LDH-P-C-510, Pico Quant GmbH) pulsed at frequencies between 100 kHz and 40 MHz, with a pulse duration of 117 ps and fluence of 30 nJ/cm⁻². The samples were exposed to the pulsed light source until a stable photoemission was obtained. The PL was collected using a high resolution monochromator and hybrid photomultiplier detector assembly (PMA Hybrid 40, PicoQuant GmbH).

Relative intensity steady state photoluminescence spectra were measured with a Horiba Flurolog spectrofluorimeter. The exposed area and the position of the crystals were carefully controlled to achieve similar illumination and collection conditions. The excitation wavelength was 535 nm.

UV-Vis Absorption

Absorption spectra were recorded on a Varian Cary 300 UV-Vis spectrophotometer.

Photoluminescence Quantum Efficiency (PLQE)

PLQE values were determined following the method of De Mello et al. (Adv. Mater., 1997, 9, 230-232) using a 532 nm continuous wave laser excitation source (Roithner, RLTMLL-532 2 W) to illuminate a sample in an integrating sphere (Newport, 70682NS), and the laser scatter and PL were collected using a fibre-coupled spectrometer (Ocean Optics MayaPro). The beam intensity was modified using neutral density filters.

Scanning Electron Microscopy

A field emission scanning electron microscope (Hitachi S-4300) was used to acquire SEM images. The instrument uses an electron beam accelerated at 2.0 kV, enabling operation at a variety of currents.

Device Fabrication

Devices were fabricated using fluorine-doped tin oxide (FTO) coated glass (Pilkington) as the transparent electrode. FTO was etched with 2M HCl and zinc powder to obtained the required electrode pattern. The substrate was then cleaned following the same cleaning procedure as the spectroscopy slides.

For n-i-p devices, the electron-transport layer SnO₂ was prepared by dissolving SnCl₄.5H₂O precursor in IPA (17.5 mg/ml) and stirring for 30 minutes before depositing via spin-coating onto FTO at 3000 r.p.m. for 30 s. The film was then annealed at 100° C. for 20 minutes and then at 180° C. for 60 minutes. The substrates were then immersed into a chemical bath, which consisted of SnCl₂ 2H₂O (Sigma-Aldrich) in deionised water (0.012 M), 20.7 mM urea (Sigma-Aldrich), 0.15 M HCl (Fisher scientific) and 2.87 μM 3-mercaptopropionic acid (Sigma-Aldrich). The substrates were kept in an oven at 70° C. for 180 minutes, after which they were sonicated in deionised water for 2 minutes. They were then washed with ethanol and annealed at 180° C. for 60 minutes. The electron-blocking layer was deposited as a 85 mg/ml 2,2′,7,7′-tetrakis-(N,N-di-p-methoxyphenylamine)-9,9′-spirobifluorene (spiro-OMeTAD) (Lumtec) solution in chlorobenzene. 20 μl of a lithium bis(trifluoromethanesulfonyl)imide (Li-TFSI) (520 mg/ml solution in acetonitrile) and 7.5 μl of 4-tert-butylpyridine (TBP), were then added per 1 ml of spiro-OMeTAD solution. Spin-coating was carried out at 2000 rpm for 30 s. The samples were left to oxidise in a desiccator for at least 12 hours before testing in the solar simulator. 100 nm thick silver electrodes were then deposited under high vacuum (10⁻⁶ mbar) through a shadow mask.

For the p-i-n inverted devices, poly[N,N′-bis(4-butylphenyl)-N,N′-bisphenylbenzidine](polyTPD, 1-Material) used as the hole transporting material was dissolved in toluene at a concentration of 1 mg/mL along with 20 wt % of 2,3,5,6-Tetrafluoro-7,7,8,8-tetracyanoquinodimethane (F4-TCNQ, Lumtec) whilst for the electron transporting materials, [6,6]-Phenyl-C61-butyric acid methyl ester (PC61BM, 99% Solenne BV) and bathocuproine (BCP, 98% Alfa Aesar) were dissolved in chlorobenzene and isopropanol at a concentration of 20 mg/mL and 0.5 mg/mL, respectively. The perovskite absorber layer was deposited using a solvent-quenching method (i.e. dropping antisolvent anisole (400 μL) 10 sec before the end of the spin-cast process). In this example, only the perovskite absorber layer and the electron-transporting layers were processed in a nitrogen-filled glovebox (O₂, H₂O<1 ppm); the rest of the fabrication as well as the incomplete devices were processed and handled in ambient air. Finally, the inverted cells were completed by thermal evaporation of 70 nm of silver contacts under vacuum (10⁻⁶ mbar).

External Quantum Efficiency Measurements

External quantum efficiency (EQE) was measured via a custom built Fourier transform photocurrent spectrometer based on a Bruker Vertex 80v Fourier Transform Interferometer. Devices were illuminated with an AM1.5 filtered solar simulator. Devices were calibrated to a Newport-calibrated reference silicon solar cell with known external quantum efficiency. The devices were masked with a metal aperture with a defined active area, 0.0919 cm².

Current-Voltage Characterisation

Solar cell performance was measured using a class AAB ABET sun 2000 solar simulator that was calibrated to give simulated AM 1.5 sunlight at an irradiance of 100 mW/cm². The irradiance was calibrated using an NREL calibrated KG5-filtered silicon reference cell. Current-voltage curves were recorded using a sourcemeter (Keithley 2400). All solar cells were masked with a metal aperture that was used to define the active area of the devices, which in this case was 0.0925 cm².

X-Ray Diffraction Measurement

Diffraction patterns were obtained with a Panalytical X-Pert Pro MPD using Cu Kα radiation. Samples were either thin films deposited on glass or powders mounted using a small amount of grease.

Results and Discussion

Mechanism for Photo-Brightening

The following mechanism for photo-brightening in methylammonium lead triiodide (MAPbI₃) is proposed, using Kroger-Vink defect notation.

The reaction is initiated by the generation of an electron-hole pair upon absorption of a photon. The photo-generated hole can combine with an iodide ion to form a halide atom. It is plausible that this reaction occurs along with a rapid site exchange of the iodide from a regular to interstitial lattice site.

I^{x}_{I}+h^{⋅}→I^{⋅}_{I}

Two halide atoms can combine to give an iodine molecule, which is a volatile gas which can then desorb from the surface to give two anion vacancies.

2I^{⋅}_{I}→I_{2(g)}+2V^{⋅}_{I}

These vacancies may trap an electron which can then react with a lead ion to form a Pb⁺ ion.

V^{⋅}_{I}+e′→(V^{⋅}_{I}e′)^{x}

Pb^{x}_{Pb}+(V^{⋅}_{I}e′)^{x}→(V^{⋅}_{I}Pb_{Pb}′)^{x}

A disproportionation reaction then occurs to generate atomic lead, Pb_{Pb}″ charge compensated by two anion vacancies.

2Pb_{Pb}′→Pb^{x}_{Pb}+Pb_{Pb}″

In the presence of oxygen, the formation of the superoxide species under illumination occurs. Due to the reactivity of superoxide as a strong proton scavenger and an initiator of radical reactions, O₂⁻ will readily abstract the acidic proton on the MA cation if in close proximity to the ammonium group to form a hydroperoxyl radical. It is noted that for this reaction to happen, oxygen does not need to be trapped in a iodide vacancy but can be simply physisorbed onto the surface.

O₂+e⁻→O₂⁻

CH₃NH₃⁺+O₂⁻↔CH₃NH_{2(g)}+HO₂^{⋅}

This process generates methylamine that can easily escape in the gas phase causing degradation. This reaction will be catalysed in the presence of an acid, giving a plausible explanation for the large photo-brightening observed when acidic compounds are used as perovskite precursors such as in the “acetate route”. The pKa dependence of this reaction and the stronger acidity of MA also explains why the process of photo-brightening has so far only been observed in perovskites with MA as the A-site cation, an observation which previous reports on photo-brightening have been unable to explain.

Hydrogen peroxide can then be generated by either hydroperoxyl radical electron abstraction, the reaction with another hydroperoxyl or the reaction of superoxide with water.

Improvements to PLQE measurements moving from dry air to humid air and later on visible degradation of the perovskite by loss of MA (and formation of PbI₂) suggest that all these processes are likely contributing while light soaking.

2HO₂^{⋅}↔O₂+H₂O₂

HO₂^{⋅}+e⁻→HO₂⁻

O₂⁻+H₂O→½O₂+H₂O₂

The introduction of oxygen to create superoxide species subsequently generates hydrogen peroxide, a strong oxidant in close proximity to a lead-rich surface. The reaction of Pb with H₂O₂ leads to the formation of Pb(OH)₂. It can be inferred that this reactivity can be applied to the atomic lead generated on the perovskite surface as shown in the above equations.

Pb+H₂O₂→Pb(OH)₂

PbO could form through the reaction of peroxide anions with lead octahedra in the perovskite lattice via the formation of two covalent Pb—O bonds. The distorted octahedra subsequently fragment to form PbO degradation products. Similarly, atomic lead on the perovskite surface can react with peroxide to generate localised PbO structures. This behaviour of reactivity is outlined in the following equation.

Pb+H₂O₂→PbO+H₂O

In summary, this mechanism proposes a comprehensive understanding of the reactivity of MAPbI₃ under ambient conditions and gives insights into the origins of instability in metal halide perovskites. This whole process can occur on the timescale of many hours and is strictly dependent on the conditions of humidity and light intensity in air.

Oxidation with Hydrogen Peroxide

In order investigate the proposed mechanism, hydrogen peroxide was applied directly to a perovskite as a post-treatment. It was found that it was possible to mimic the process of photo-brightening and to reproducibly generate the passivating lead oxide species. Similar improvements to the material's optoelectronic properties were observed. Furthermore, by not generating hydrogen peroxide in situ, the series of degradation reactions responsible for its formation could be side-stepped. This meant that the presence of methylammonium is no longer necessary as a proton source and can be substituted for other less acidic cations such as formamidinium (FA) which, when combined with a small amount of caesium and a mixed halide stoichiometry, can form stable perovskite thin-films with reported n-i-p device efficiencies that surpass 20%.

Two methods of H₂O₂ deposition were developed: one solvent-based and the other in the gas phase, described in detail in the Methods section. The wet deposition method consists in dipping briefly thin-film perovskite in a low-concentration solution of H₂O₂ in isopropanol (IPA) whereas the gas phase deposition method uses urea hydrogen peroxide (UHP) to generate an atmosphere of pure H₂O₂ gas to which the perovskite was exposed in a chamber. Thin films of FA_{0.83}Cs_{0.17}Pb(Br_{0.1}I_{0.9})₃ using a solvent quenching route (see Methods).

PL spectroscopy was used to investigate the effects of the H₂O₂ post-treatment on the optoelectronic properties of the perovskites. In FIG. 2, steady-state PL measurements on thin-films of FA_{0.83}Cs_{0.17}Pb(I_{0.83}Br_{0.17})₃ treated via the wet deposition method are shown, where the thin-film perovskite is briefly dipped in a low-concentration solution of H₂O₂ in isopropanol (IPA).

To compare the different PL decays, ti/e, the time taken for the normalised intensity to reach 1/e, was used as an indicator of the radiative lifetime. A longer lifetime indicates decreased non-radiative recombination and, generally a higher quality material due to a reduced defect density. For films treated with 0.013 M and 0.026 M solutions of H₂O₂ radiative lifetimes of 140 ns and 281 ns respectively were observed, which represents a significant increase compared to a mean, untreated control value of 40±5 ns. Steady state measurements show a more than 10 times increase in the relative PL, measured by integrating the area under each curve. Both of these findings suggest a large reduction in non-radiative pathways, consistent with the passivation of defects at the surface. Interestingly, the initial fast component of the decay observed in the first 50 ns is almost completely eliminated with the high concentration treatment of H₂O₂. At the low excitation fluence used here (carrier density ˜10¹⁵ cm⁻³), this initial decay is likely to be related to fast trapping which is detrimental to the device performance. To exclude the possibility that the improvement is due to water contained in the peroxide solution, a control measurement was performed with an equivalent concentration of water in IPA and no improvements to PL were observed.

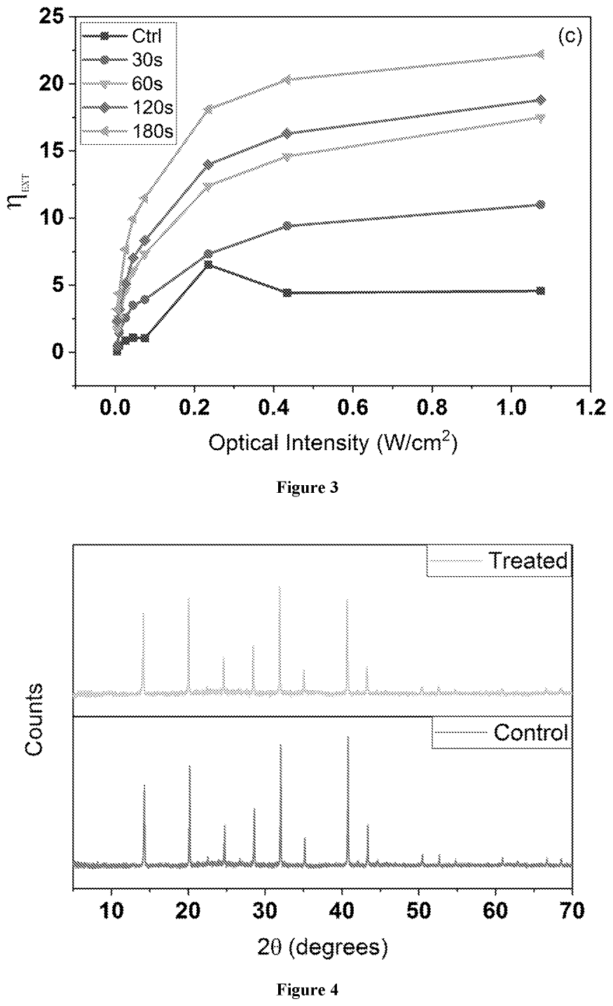

Next, the PL quantum efficiency was measured as function of irradiance for perovskite films treated via the gas deposition method for various amounts of time between 0 and 180 s and the results are shown in FIG. 3. A maximum PLQE of 22.1% at 1.1 W/cm² is found for the films treated during 180 s, in comparison to 4.4% for the untreated control film. A strong dependence of the PLQE on the excitation power was found for all samples, which is consistent with a trap-filling mechanism. However, treated films evolve more quickly to their maximum efficiency and the final steady-state efficiency is significantly increased, which is consistent with increased radiative efficiency due to passivation.

Interestingly, a slight colour change of the film surface was observed for films treated with higher concentrations of hydrogen peroxide. UV-Vis absorbance spectra revealed that the absorption onset remained constant after treatment indicating that no chemical change happened. The colour change was instead attributed to an optical interference caused by the presence of a new layer forming on top of the perovskite surface with a different refractive index. This is consistent with the proposed mechanism of the formation of lead oxide species coating the surface. Further, X-ray diffraction spectra, shown in FIG. 4, confirm that no change to the bulk perovskite crystal structure occurs and that the treatment is purely a surface effect.

To benchmark the improvements to PLQE with H₂O₂ to other passivation treatments comparative measurements were taken for current state-of-the-art passivation treatments phenethylammonium iodide (PEAI) and butylammonium iodide (BAI). FIG. 5 shows the PLQE for films treated with the different passivation agents under 1 sun irradiance. A PLQE of 6.4% at 1 sun irradiation was measured for films treated with H₂O₂ for 60 s, in comparison to 1.4% for untreated films, 1.7% for BAI and 2.3% for PEAL. H₂O₂ treatment is more effective than some of the current best performing passivation agents in reducing the concentration of defects leading to non-radiative recombination.

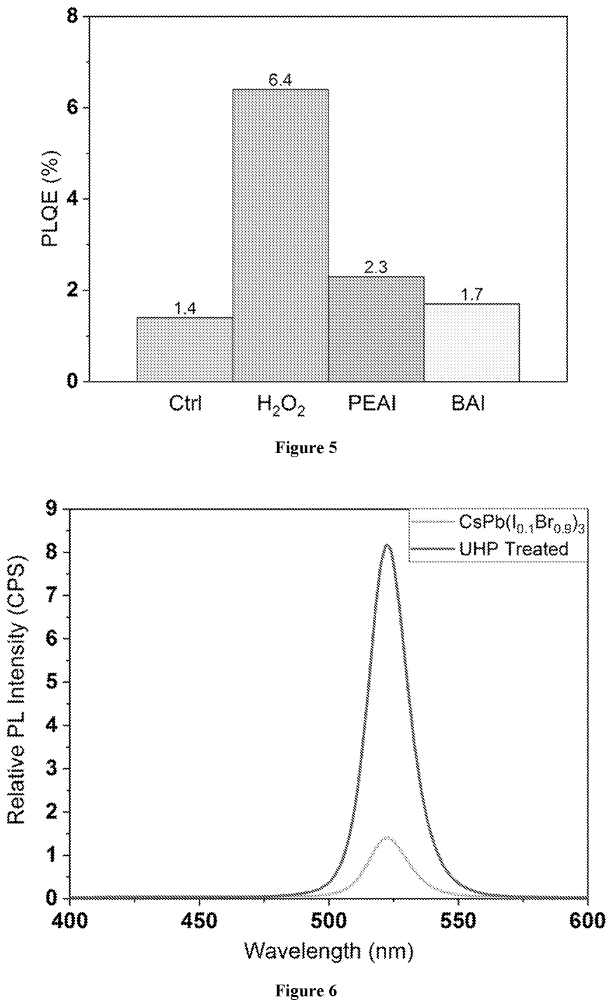

The potential use of oxidative passivation was also investigated on a pure inorganic perovskite, CsPb(Br_{0.9}I_{0.1})₃. According to the proposed mechanism, proton sources (such as MA or FA cations) are required for the in-situ generation of H₂O₂. Exposing the perovskites to hydrogen peroxide should avoid this dependence on the presence of a proton source. This was confirmed by an observation of a five times increase in steady-state PL measurements compared to the control when CsPb(Br_{0.9}I_{0.1})₃ was treated via the gas deposition method for five minutes (FIG. 6).

In order to gain insight into the chemical nature of the perovskite surface before and after oxidative treatments, x-ray photoemission spectroscopy (XPS) measurements were conducted. No significant changes to the Br, I and Cs environments are observed in both the pristine and treated films.

The Pb 4f scans show peaks observed at 138.7 eV and ˜137 eV, attributed to Pb²⁺ and Pb⁰ respectively. These peaks are observed for all samples except those exposed to 10 minutes of treatment, in this case only one peak at 138.7 eV is observed. The loss of the peak corresponding to Pb⁰ in the films which have undergone treatment for the longest time is accompanied by a significant broadening of the peak. This suggests that the Pb⁰ previously observed within the film is being oxidised to Pb²⁺ and the peak broadening observed is typical for metal oxide species. 0 is scans for all samples show three oxygen species to be present within the surface of all thin films. These species are observed at ˜533 eV, 531 eV and 530 eV, with slight variations in the exact peak position between samples, and have been attributed to organic C═O (533 eV), peroxide O₂²⁻/hydroxide OH⁻ (531 eV) and oxide O²⁻ (530 eV). Peroxide and hydroxide O 1 s peak positions are at very similar binding energies and it is likely that both these species are contributing to the 531 eV peak, in agreement with the proposed mechanism. Whilst all three species of oxygen are observed in the pristine films, the relative ratios of the different species varies between pristine and treated films. It is important to note that there is a signal corresponding to PbO in the O 1 s scan of the pristine films which arises due to the samples being prepared and stored in air. However, there is a significant increase in the signal for PbO observed in the treated samples. This finding combined with the loss of the peak attributed to Pb⁰ in the Pb 4f scans suggests that hydrogen peroxide is the reagent responsible for generating lead oxide on the surface of perovskite, an observation in good agreement with the proposed mechanism.

From these findings, it can be concluded that hydrogen peroxide is performing an “oxidative passivation” of charge-trapping atomic lead at the perovskite surface, forming covalent lead oxygen bonds. Encouragingly, this behaviour matches the reactivity the proposed mechanism of photo-brightening in the equations above.

Use of Ozone and Oxygen Plasma Treatments

The effects of oxygen plasma and ozone on a perovskite were also investigated.

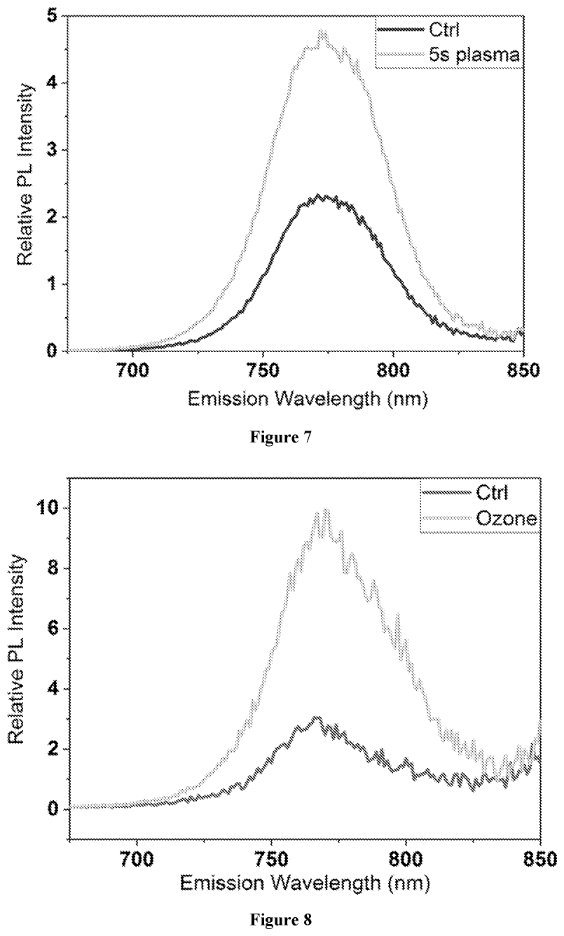

For the oxygen plasma treatment, films of FA_{0.83}Cs_{0.17}Pb(I_{0.83}Br_{0.17})₃ were prepared and then treated in a low-pressure oxygen plasma system for short intervals. Exposure to oxygen plasma was found to increase the radiative lifetimes of the films compared with the control. In particular, time-resolved photoluminescence measurement of film of FA_{0.83}Cs_{0.17}Pb(I_{0.83}Br_{0.17})₃ after treatment with an exposure to oxygen plasma for 2 s and 5 s, compared to a control lead to observed radiative lifetimes of τ_{1/e} (ctrl)=40 ns, τ₁/e (“2 s”)=118 ns, and τ₁/e (“5 s”)=226 ns. Steady state PL measurements are shown in FIG. 7. A substantial increase in PL lifetimes and intensities were accordingly observed.

Films of MAPbI₃ perovskite were also exposed to an atmosphere of oxygen with ˜30% ozone. Steady state PL measurements are shown in FIG. 8. A substantial increase in PL intensity was observed.

H₂O₂ Treatment for Photovoltaic Devices

By using directly H₂O₂ as an oxidising passivating agent, a scalable and highly effective post-treatment is proposed. The practical use of the gas-phase treatment in photovoltaic devices of both n-i-p and p-i-n configurations was done as follows.

Planar heterojunction solar cells were fabricated on glass substrates with the following architectures:
FTO/SnO₂/FA_{0.83}Cs_{0.17}Pb(I_{0.83}Br_{0.17})₃ perovskite/spiro-OMeTAD/Ag (n-i-p); and
FTO/polyTPD/FA_{0.83}Cs_{0.17}Pb(Br_{0.1}I_{0.9})₃ perovskite/PCBM/BCP/Ag (p-i-n).

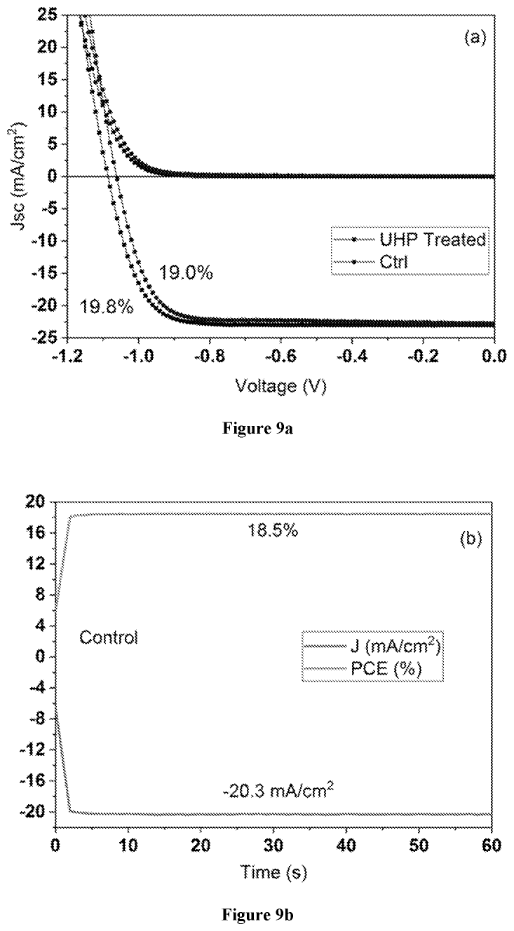

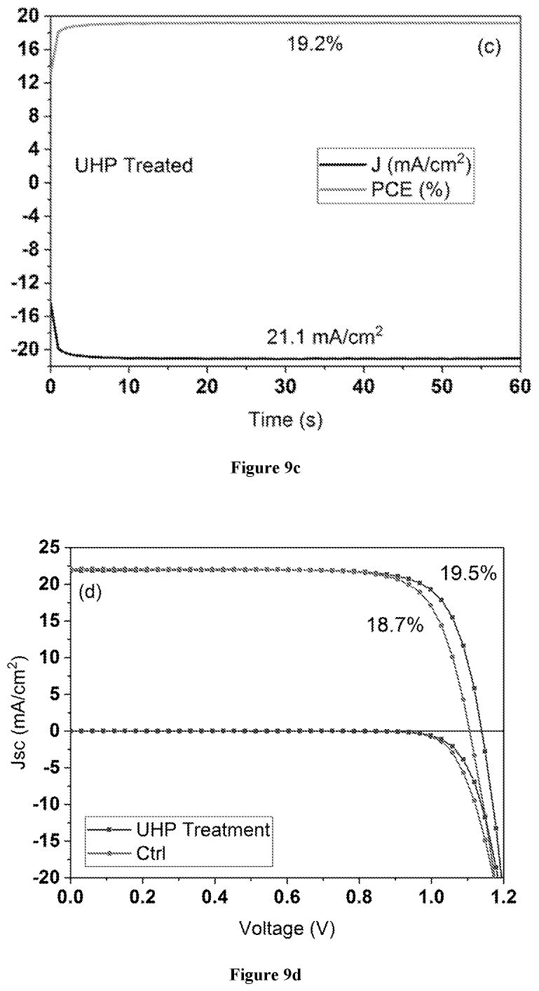

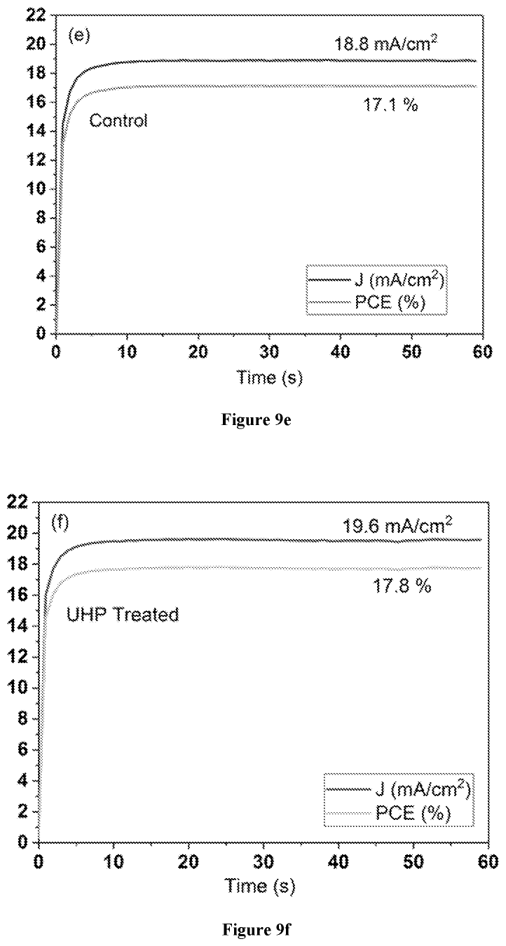

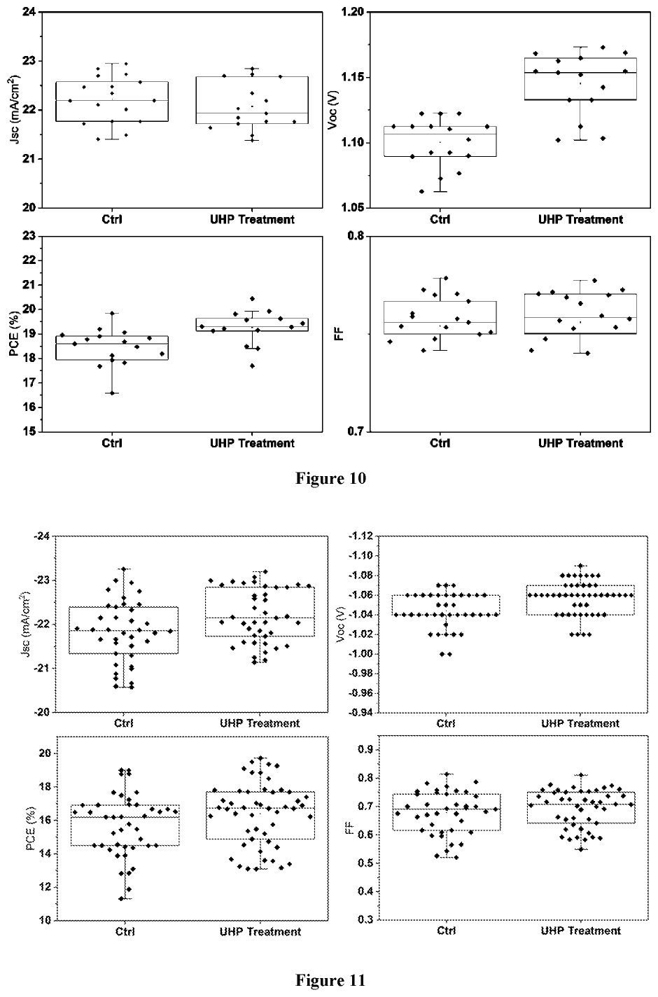

The current-voltage (J-V) curves of the control devices and the devices treated with hydrogen peroxide via the gas deposition method are shown in FIG. 9. Champion n-i-p devices for control films of FA_{0.83}Cs_{0.17}Pb(I_{0.9}Br_{0.1})₃ had the following scanned parameters; J_{sc}, =22.9 mA/cm², V_{oc}=1.11 V, FF=0.78, PCE=19.8%. Champion devices of devices treated with Urea Hydrogen Peroxide showed 60 mV improvements of V_{oc} up to 1.17 V, and to PCE up to 20.4%. There were slight changes to FF and a small decrease in J_{sc}. Champion inverted p-i-n devices showed similar improvements to the open-circuit voltage, typically increasing from 1.06 V to 1.09 V for best performance devices with power conversion efficiencies improving by almost a whole percentage to reach 19.8%. Average values of these parameters for several control devices and those treated with urea hydrogen peroxide are summarised in Table 1. The steady-state power outputs of inverted p-i-n devices show improvements upon treatment with H₂O₂ from 18.5% to 19.2%. The same increase is not observed for n-i-p devices which have a slightly lower photocurrent, possibly due to suppressed charge extraction by the oxidised lead layer in this device architecture. Encouragingly, the extent of hysteresis appears to reduce upon treatment. Box plots of device performance for the n-i-p and p-i-n devices are shown in FIGS. 10 and 11 respectively.

TABLE 1
Device performance parameters for n-i-p and inverted p-i-n
FA_{0.83}Cs_{0.17}Pb(Br_{0.1}I_{0.9})₃ devices treated with Hydrogen Peroxide
via the gas deposition method compared to control.

| | J_{sc} (mA/cm²) | PCE (%) | V_{oc} (V) | FF |
|---|---|---|---|---|
| n-i-p Control | 22.3 ± 0.4 | 18.5 ± 0.7 | 1.10 ± 0.02 | 0.76 ± 0.02 |
| n-i-p Treated | 22.0 ± 0.6 | 19.4 ± 0.6 | 1.15 ± 0.02 | 0.76 ± 0.01 |
| p-i-n Control | 21.9 ± 0.7 | 16.5 ± 1.2 | −1.04 ± 0.01 | 0.70 ± 0.5 |
| p-i-n Treated | 22.1 ± 0.6 | 17.4 ± 1.1 | −1.06 ± 0.01 | 0.71 ± 0.5 |

### CONCLUSIONS

In summary, H₂O₂ and other oxygen based passivating agents have been applied as a fast, non-toxic, scalable and effective post-treatment to a perovskite surface to imitate the process of photo-brightening that occurs over several hours. The same significant improvement to photoluminescence is observed after this treatment and a series of experimental techniques were used on these samples to verify our mechanism and gain a greater understanding of the photo-brightening process. The mechanism highlights the instability of the methylammonium cation and the degradation route for perovskites that are exposed to light in ambient conditions. By directly applying H₂O₂ as a post-treatment on a metal halide perovskite with less acidic A-site cations (e.g. formamidinium and cesium), application of the passivation to stable, high-efficiency perovskite compositions was possible without the need for light soaking. This resulted in significant improvement to the open-circuit voltage and power-conversion efficiency, demonstrating oxidative passivation as an invaluable technique in the quest for both high luminescence and excellent charge transport. The technique is likely to open a new avenue for perovskite chemical passivation, as an alternative to molecular passivation, propelling their development for next-generation photovoltaics, LEDs and other optoelectronic devices.

### Example 2—Effect of Annealing on PLQE

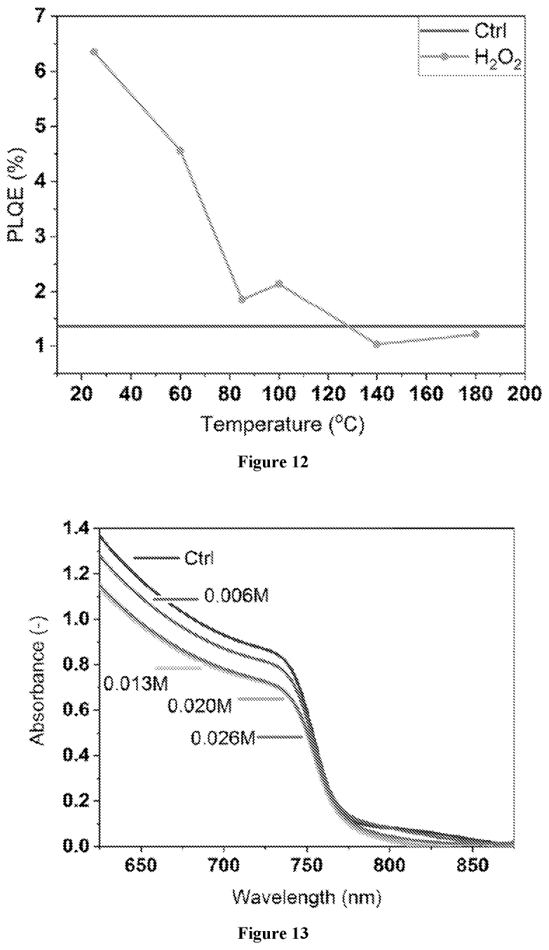

A layer of FA_{0.83}Cs_{0.17}Pb(I_{0.83}Br_{0.17})₃ was exposed to hydrogen peroxide gas generated from UHP for 60 seconds. The passivated perovskite was then held at different temperatures from 25° C. (no annealing) to 180° C. and the photoluminescence quantum efficiency (PLQE) values were measured. As shown in FIG. 12, it was found that the highest PLQE was observed with no annealing. The solid line in FIG. 12 is the PLQE of the as crystallised control film with no post annealing.

### Example 3—Effect of Different Hydrogen Peroxide Concentrations on UV-Vis Absorbance

A layer of FA_{0.83}Cs_{0.17}Pb(I_{0.83}Br_{0.17})₃ was treated by H₂O₂ via the wet deposition method with different H₂O₂ concentrations. FIG. 13 shows the UV-Vis absorption spectra. The absorption onset remains constant indicating the treatment has no effect on the bulk perovskite material but is just a surface effect. The relatively minor changes in optical absorption spectra are attributed to changes in reflection due to the alteration of the surface. This is further indicated by the change of the interference pattern visible below the band edge.

### Example 4—Performance Parameters for n-i-p Devices

Twenty-four n-i-p devices were produced with the architecture FTO/SnO₂/FA_{0.83}Cs_{0.17}Pb(I_{0.83}Br_{0.17})₃ perovskite/spiro-OMeTAD/Ag. The twenty four devices were on four separate substrates. The devices were treated with gas phase hydrogen peroxide. The treated devices were compared with control devices and performance parameters are shown in Table 2 below.

TABLE 2

| | J_{sc} | | | | SPO |
|---|---|---|---|---|---|
| | (mA/cm²) | PCE (%) | V_{oc} (V) | FF | (%) |
| n-i-p | 21.9 ± 0.4 | 17.6 ± 0.4 | 1.09 ± 0.01 | 0.73 ± 0.03 | 17.1 |
| Control | | | | | |
| n-i-p | 21.7 ± 0.6 | 18.6 ± 1.0 | 1.13 ± 0.01 | 0.75 ± 0.03 | 17.8 |
| Treated | | | | | |

1. A process for producing a passivated semiconductor, which process comprises treating a semiconductor with a passivating agent, wherein:
the semiconductor comprises a crystalline compound comprising: (i) one or more first cations (A); (ii) one or more metal cations (M); and (iii) one or more anions (X); and
the passivating agent comprises a compound comprising an oxygen-oxygen single bond.

2. A process according to claim 1, wherein the passivating agent comprises: a compound comprising a peroxide group; a compound comprising a hydroperoxyl group; a compound comprising a perester group; a compound comprising a peranhydride group; a compound comprising a peracid group; or ozone.

3. A process according to claim 1 or claim 2, wherein the passivating agent comprises: a compound of formula R—O—O—R; a compound of formula R—C(O)—O—O—R; or a compound of formula R—C(O)—O—O—C(O)—R,
wherein:
each R is independently selected from H, unsubstituted or substituted C₁₋₈ alkyl, unsubstituted or substituted C₁₋₈ alkenyl and unsubstituted or substituted aryl, optionally wherein each R is bound together to form a ring.

4. A process according to any one of the preceding claims, wherein the passivating agent comprises a compound selected from hydrogen peroxide, urea hydrogen peroxide, ozone, tert-butyl hydroperoxide, tert-butyl peroxybenzoate, di-tert-butyl peroxide, 2-butanone peroxide, cumene hydroperoxide, dicumyl peroxide, bis(trimethylsilyl) peroxide, benozyl peroxide, diacetyl peroxide, diethyl ether peroxide, dipropyl peroxydicarbonate, methyl ethyl ketone peroxide, peracetic acid, performic acid, peroxybenzoic acid and meta-chloroperoxybenzoic acid.

5. A process according to any one of the preceding claims, wherein the passivating agent comprises hydrogen peroxide or ozone,
preferably wherein the passivating agent comprises hydrogen peroxide.

6. A process according to any one of the preceding claims, wherein the semiconductor comprises a perovskite.

7. A process according to any one of the preceding claims, wherein the semiconductor comprises a metal halide perovskite.

8. A process according to any one of the preceding claims, wherein the semiconductor comprises a crystalline compound of formula [A][M][X]₃, wherein: [A] comprises the one or more first cations; [M] comprises the one or more metal cations; and [X] comprises the one or more anions, which one or more anions comprise one or more halide anions selected from I⁻, Br⁻ and Cl⁻.

9. A process according to any one of the preceding claims, wherein the one or more first cations (A) are selected from K⁺, Rb⁺, Cs⁺, (NR¹R²R³R⁴)⁺, (R¹R²N═CR³R⁴)⁺, (R¹R²N—C(R⁵)═NR³R⁴)⁺ and (R¹R²N—C(NR⁵R⁶)═NR³R⁴)⁺, wherein each of R¹, R², R³, R⁴, R⁵ and R⁶ is independently H, unsubstituted or substituted C₁₋₂₀ alkyl or unsubstituted or substituted aryl,
preferably wherein the one or more first cations are selected from Cs⁺, (CH₃NH₃)⁺ and (H₂N—C(H)═NH₂)⁺.

10. A process according to any one of the preceding claims, wherein the one or more metal cations (M) are selected from Pb²⁺, Ca²⁺, Sr²⁺, Cd²⁺, Cu²⁺, Ni²⁺, Mn²⁺, Fe²⁺, Co²⁺, Pd²⁺, Ge²⁺, Sn²⁺, Yb²⁺, Eu²⁺, Bi³⁺, Sb³⁺, Pd⁴⁺, W⁴⁺, Re⁴⁺, Os⁴⁺, Ir⁴⁺, Pt⁴⁺, Sn⁴⁺, Pb⁴⁺, Ge⁴⁺ or Te⁴⁺,
preferably wherein the one or more metal cations comprise Pb²⁺ and/or Sn²⁺.

11. A process according to any one of the preceding claims, wherein the semiconductor comprises a crystalline compound of formula [A]Pb_{z}Sn_{(1-z)}[X]₃, where z is from 0.0 to 1.0.

12. A process according to any one of the preceding claims, wherein the semiconductor comprises a crystalline compound of formula Csₓ(H₂N—C(H)═NH₂)₍₁₋ₓ₎PbBr_{3y}I_{3(1-y)}, where x is from 0.0 to 1.0 and y is from 0.0 to 1.0.

13. A process according to any one of the preceding claims, wherein treating the semiconductor with the passivating agent comprises exposing the semiconductor to a composition comprising a solvent and the passivating agent,
preferably wherein the composition comprising the solvent and the passivating agent comprises a solution of the passivating agent in the solvent.

14. A process according to claim 13, wherein the solvent comprises one or more polar solvents,
preferably wherein the solvent comprises water and isopropanol.

15. A process according to any one of the preceding claims, wherein treating the semiconductor with the passivating agent comprises exposing the semiconductor to an aqueous solution of hydrogen peroxide,
preferably wherein the aqueous solution of hydrogen peroxide comprises hydrogen peroxide at a concentration of from 0.001 to 0.1 M.

16. A process according to any one of claims 1 to 12, wherein treating the semiconductor with the passivating agent comprises exposing the semiconductor to a vapour comprising the passivating agent.

17. A process according to claim 16, wherein treating the semiconductor with the passivating agent comprises exposing the semiconductor to a vapour comprising hydrogen peroxide,
preferably wherein the process further comprises generating the vapour comprising hydrogen peroxide by heating a composition comprising urea hydrogen peroxide.

18. A process according to any one of the preceding claims, wherein the semiconductor is illuminated with an intensity of no greater than 0.5 kW/m² during treatment with the passivating agent, optionally wherein the semiconductor is illuminated with an intensity of no greater than 0.1 kW/m² during treatment with the passivating agent.

19. A process according to any one of the preceding claims, wherein the semiconductor is treated with the passivating agent for less than 1 hour, optionally wherein the semiconductor is treated with the passivating agent for less than 1 minute.

20. A process according to any one of the preceding claims, wherein the passivated semiconductor has an increased photoluminescence lifetime and/or an increased photoluminescence intensity compared with the semiconductor before passivation.

21. A process for producing a semiconductor device, wherein the process comprises producing a passivated semiconductor by a method according to any one of the preceding claims.

22. A process according to claim 21, wherein the semiconductor device is an optoelectronic device,
preferably wherein the optoelectronic device is a photovoltaic device or a light emitting device.

23. A composition comprising:
(i) a semiconductor as defined in any one of claims 1 and 6 to 12; and
(ii) a passivating agent as defined in any one of claims 1 to 5,
wherein the concentration of the passivating agent is greater than or equal to 0.001 mol % relative to the amount of the semiconductor.

24. A composition according to claim 23, wherein the semiconductor comprises a perovskite and the passivating agent comprises hydrogen peroxide.

25. Use of a composition comprising a passivating agent for passivating a semiconductor which is illuminated with an intensity of no greater than 0.5 kW/m² during passivation, wherein:
the semiconductor comprises a crystalline compound comprising: (i) one or more first cations (A); (ii) one or more metal cations (M); and (iii) one or more anions (X); and
the passivating agent comprises a compound comprising an oxygen-oxygen single bond or an oxygen-oxygen double bond.

26. Use according to claim 25, wherein passivating agent comprises oxygen plasma or a compound as defined in any one of claims 1 to 5.
